(19) United States
(12) Patent Application Publication
(10) Pub. No.: US 2013/0175591 A1
(43) Pub. Date: Jul. 11, 2013

(54) CAPACITIVE DEVICE, SEMICONDUCTOR UNIT, AND ELECTRONIC APPARATUS

(71) Applicant: Sony Corporation, Tokyo (JP)

(72) Inventor: Masaaki Bairo, Kanagawa (JP)

(73) Assignee: SONY CORPORATION, Tokyo (JP)

(21) Appl. No.: 13/732,854

(22) Filed: Jan. 2, 2013

(30) Foreign Application Priority Data
Jan. 10, 2012 (JP) 2012-002442

(51) Int. Cl. H01L 27/06

(52) U.S. Cl. CPC H01L 27/0629
USPC 257/296

(57) ABSTRACT

A capacitive device includes: a first capacitive element including a first well region having a first conduction type, a first gate electrode, and first semiconductor layers each formed of an impurity layer having a second conduction type opposite to a conduction type of the first well region; and a second capacitive element electrically connected in parallel to the first capacitive element, the second capacitive element including a second well region having the first conduction type, a second gate electrode, and second semiconductor layers each formed of an impurity layer having the same first conductive type as a conduction type of the second well region.

### BACKGROUND

The present disclosure relates to a capacitive device, and particularly relates to a capacitive device configured of a metal insulator semiconductor (MIS) structure. In addition, the disclosure relates to a semiconductor unit incorporating the capacitive device, and an electronic apparatus including the semiconductor unit.

A MOS capacitive device, which may be produced in a common complementary-metal-oxide-semiconductor (CMOS) process, has been proposed as a capacitive device incorporated in a semiconductor unit (see Japanese Unexamined Patent Application Publication Nos. 2008-288576, 2005-197396, and 2002-158331). The MOS capacitive device may be produced in a common CMOS process, and therefore may be integrated with a metal-oxide-semiconductor field-effect transistor (MOSFET) on the same substrate without increasing manufacturing cost.

FIG. 26 illustrates a schematic configuration of a typical MOS capacitive device 100 described in Japanese Unexamined Patent Application Publication No. 2008-288576. As illustrated in FIG. 26, the MOS capacitive device 100 includes a p-type semiconductor substrate 102, and an n-type well region 103 provided in the semiconductor substrate 102. Furthermore, the capacitive device 100 includes two diffusion layers 104 each including an n+impurity layer provided in the well region 103, and a gate electrode 105 provided on the semiconductor substrate 102.

The diffusion layers 104, which are provided at the sides of the gate electrode 105, are in general formed by ion implantation in a self-aligned manner with the gate electrode 105 as a mask after formation of the gate electrode 105. The gate electrode 105 is provided on the semiconductor substrate 102 with a gate oxide film 106 therebetween, and is formed of, for example, polysilicon doped with an n-type impurity.

In such a MOS capacitive device 100, a first electrode 107 is connected to the gate electrode 105, and a second electrode 108 is connected to the diffusion layers 104, so that a desired voltage is applied between the gate electrode 105 and the diffusion layers 104. This results in formation of capacitance mainly including gate capacitance and junction capacitance between the well region 103 and the semiconductor substrate 102.

FIG. 27 illustrates C-V characteristics of the MOS capacitive device 100 illustrated in FIG. 26. In FIG. 27, the horizontal axis indicates a bias voltage (V) applied between the gate electrode 105 and the diffusion layers 104, and the vertical axis indicates capacitance (C). It is to be noted that FIG. 27 shows variations in capacitance at the diffusion layers 104 set to 0 V.

As illustrated in FIG. 27, the capacitance of the MOS capacitive device 100 varies with variations in voltage applied to the gate electrode 105. In this way, the MOS capacitive device 100 has a capacitance that highly depends on a bias voltage applied between the gate electrode 105 and the diffusion layers 104. It is therefore difficult to apply the typical MOS capacitive device to a circuit requested to have an absolutely accurate capacitance value.

Japanese Unexamined Patent Application Publication No. 2005-197396 (JP-A-2005-197396) proposes a complementary MOS capacitive device including a MOS capacitive device provided in an n-type well (hereinafter, referred to as n-type capacitive device) and a MOS capacitive device provided in a p-type well (hereinafter, referred to as p-type capacitive device) connected in parallel. In JP-A-2005-197396, a complementary MOS capacitive device is used as the MOS capacitive device provided in a substrate in order to reduce bias dependence of a capacitance value.

In a common manufacturing process of CMOS-LSI, however, both the n-type capacitive device and the p-type capacitive device are not necessarily registered as available devices. In addition, the threshold voltages of both the n-type and p-type capacitive devices are necessary to be optimized to achieve highly flat C-V characteristics. Consequently, the threshold voltage is necessary to be optimized individually for each of the MOS capacitive device and the MOSFET, leading to an increase in manufacturing cost.

Japanese Unexamined Patent Application Publication No. 2002-158331 proposes a semiconductor unit having capacitance formed between lines in a wiring layer provided on a semiconductor substrate. Although such a capacitive device using lines has a remarkably small bias dependence of a capacitance value compared with the MOS capacitive device, the capacitive device has a small capacitance value per unit area, which is disadvantageous for a reduction in size of a circuit.

### SUMMARY

It is desirable to provide a capacitive device having a reduced bias dependence of a capacitance value without a significant increase in manufacturing cost. In addition, it is desirable to provide a semiconductor unit incorporating the capacitive device, and an electronic apparatus including the semiconductor unit.

According to an embodiment of the disclosure, there is provided a capacitive device including: a first capacitive element including a first well region having a first conduction type provided in a region close to a surface of a substrate, a first gate electrode provided on the substrate with a first gate insulating film therebetween, and first semiconductor layers provided at positions interposing a region therebetween, the region corresponding to the first gate electrode on the surface of the first well region, and the first semiconductor layers each being formed of an impurity layer having a second conduction type opposite to a conduction type of the first well region; and a second capacitive element electrically connected in parallel to the first capacitive element, the second capacitive element including a second well region having the first conduction type provided in a region close to the surface of the substrate, a second gate electrode provided on the substrate with a second gate insulating film therebetween, and second semiconductor layers provided at positions interposing a region therebetween, the region corresponding to the second gate electrode on the surface of the second well region, and the second semiconductor layers each being formed of an impurity layer having the same first conductive type as a conduction type of the second well region.

According to an embodiment of the disclosure, there is provided a semiconductor unit, including: a circuit section performing predetermined processing to an input signal; and a capacitive device provided on an input side of the circuit section, the first capacitive element including a first capacitive element and a second capacitive element electrically connected in parallel to each other, the first capacitive element including a first well region having a first conduction type provided in a region close to a surface of a substrate, a first gate electrode provided on the substrate with a first gate insulating film therebetween, and first semiconductor layers provided at positions interposing a region therebetween, the region corresponding to the first gate electrode on the surface of the first well region, and the first semiconductor layers each being formed of an impurity layer having a second conduction type opposite to a conduction type of the first well region, and the second capacitive element including a second well region having the first conduction type provided in a region close to the surface of the substrate, a second gate electrode provided on the substrate with a second gate insulating film therebetween, and second semiconductor layers provided at positions interposing a region therebetween, the region corresponding to the second gate electrode on the surface of the second well region, and the second semiconductor layers each being formed of an impurity layer having the same first conductive type as a conduction type of the second well region.

According to an embodiment of the disclosure, there is provided an electronic apparatus provided with a semiconductor unit, the semiconductor unit including: a circuit section performing predetermined processing to an input signal; and a capacitive device provided on an input side of the circuit section, the first capacitive element including a first capacitive element and a second capacitive element electrically connected in parallel to each other, the first capacitive element including a first well region having a first conduction type provided in a region close to a surface of a substrate, a first gate electrode provided on the substrate with a first gate insulating film therebetween, and first semiconductor layers provided at positions interposing a region therebetween, the region corresponding to the first gate electrode on the surface of the first well region, and the first semiconductor layers each being formed of an impurity layer having a second conduction type opposite to a conduction type of the first well region, and the second capacitive element including a second well region having the first conduction type provided in a region close to the surface of the substrate, a second gate electrode provided on the substrate with a second gate insulating film therebetween, and second semiconductor layers provided at positions interposing a region therebetween, the region corresponding to the second gate electrode on the surface of the second well region, and the second semiconductor layers each being formed of an impurity layer having the same first conductive type as a conduction type of the second well region.

In the disclosure, the first and second capacitive elements are connected in parallel to reduce bias dependence of a capacitance value.

According to the disclosure, a capacitive device having a reduced bias dependence of a capacitance value is provided. In addition, a semiconductor unit incorporating the capacitive device, and an electronic apparatus including the semiconductor unit are provided.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a schematic sectional configuration diagram of a capacitive device according to a first embodiment of the disclosure.

FIG. 2 illustrates a planar layout of the capacitive device according to the first embodiment of the disclosure.

FIG. 3 is a graph illustrating C-V characteristics of each of first and second capacitive elements, and C-V characteristics (1) of a capacitive device including the first and second capacitive elements connected in parallel, in the first embodiment.

FIG. 4 is a graph illustrating the C-V characteristics of each of the first and second capacitive elements, and C-V characteristics (2) of a capacitive device including the first and second capacitive elements connected in parallel, in the first embodiment.

FIG. 5A is an equivalent circuit diagram of the capacitive device according to the first embodiment in the case where the bias voltage of a first electrode is varied positively and negatively with a second electrode at 0 V. FIG. 5B is a graph illustrating C-V characteristics in such a case.

FIG. 6A is an equivalent circuit diagram of the capacitive device according to the first embodiment in the case where the bias voltage of a second electrode is varied positively and negatively with a first electrode at 0 V. FIG. 6B is a graph illustrating C-V characteristics in such a case.

FIG. 7 is a schematic sectional configuration diagram of a capacitive device according to a second embodiment of the disclosure.

FIG. 8 illustrates a planar layout of the capacitive device according to the second embodiment of the disclosure.

FIG. 9 is a graph illustrating C-V characteristics of each of first and second capacitive elements, and C-V characteristics of a capacitive device including the first and second capacitive elements connected in parallel, in the second embodiment.

FIG. 10 is a schematic sectional configuration diagram of a capacitive device according to a third embodiment of the disclosure.

FIG. 11 illustrates a planar layout of the capacitive device according to the third embodiment of the disclosure.

FIG. 12 is a graph illustrating C-V characteristics of each of first to third capacitive elements, and C-V characteristics of a capacitive device including the first, second, and third capacitive elements connected in parallel, in the third embodiment.

FIG. 13 is a schematic sectional configuration diagram of a capacitive device according to a fourth embodiment of the disclosure.

FIG. 14 illustrates a planar layout of the capacitive device according to the fourth embodiment of the disclosure.

FIG. 15 is a schematic sectional configuration diagram of a capacitive device according to a fifth embodiment of the disclosure.

FIG. 16 illustrates a planar layout of the capacitive device according to the fifth embodiment of the disclosure.

FIG. 17 is a schematic sectional configuration diagram of a capacitive device according to a sixth embodiment of the disclosure.

FIG. 18 is a graph illustrating C-V characteristics of the capacitive device according to the sixth embodiment and C-V characteristics of a capacitive device according to a comparative example.

FIG. 19 is a schematic sectional configuration diagram of a capacitive device according to a seventh embodiment of the disclosure.

FIG. 20A is a planar configuration diagram of first and second lines provided in second and third wiring layers, respectively, of the capacitive device according to the seventh embodiment. FIG. 20B is an equivalent circuit diagram of the capacitive device according to the seventh embodiment.

FIG. 21 is a schematic sectional configuration diagram of a capacitive device according to an eighth embodiment of the disclosure.

FIG. 22 is a schematic sectional configuration diagram of a capacitive device according to a ninth embodiment of the disclosure.

FIG. 23 illustrates a planar layout of the capacitive device according to the ninth embodiment of the disclosure.

FIG. 24 is a schematic configuration diagram of a semiconductor unit according to a tenth embodiment of the disclosure.

FIG. 25 is a schematic configuration diagram of a semiconductor unit according to an eleventh embodiment of the disclosure.

FIG. 26 is a schematic configuration diagram of a typical MOS capacitive device.

FIG. 27 is a graph illustrating C-V characteristics of the typical MOS capacitive device illustrated in FIG. 26.

### DETAILED DESCRIPTION

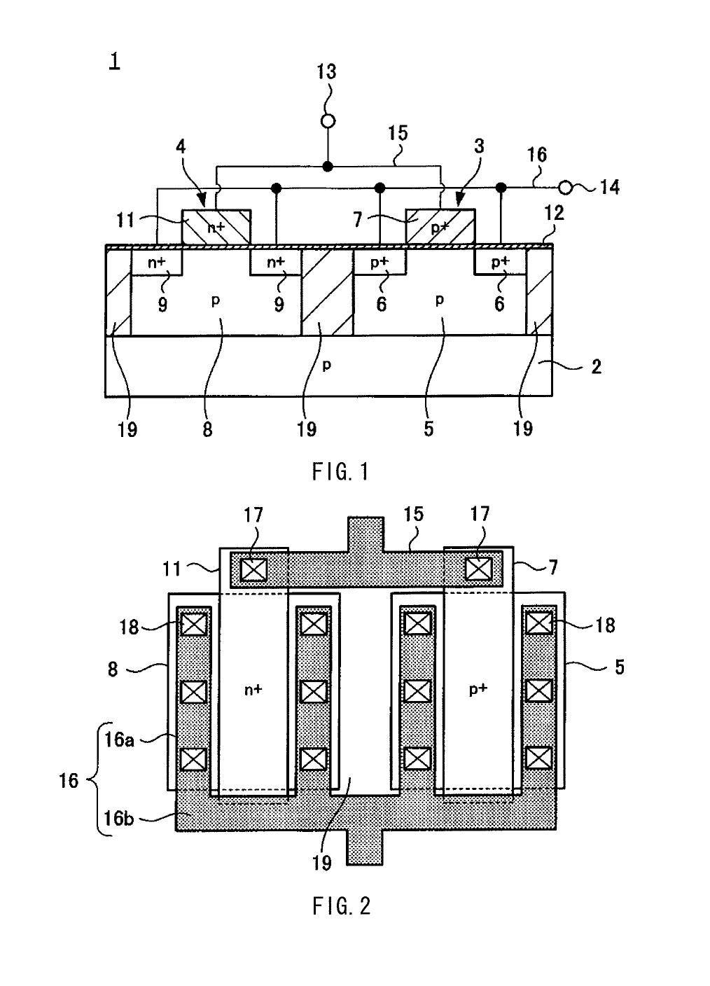

Examples of a capacitive device, a semiconductor unit incorporating the capacitive device, and an electronic apparatus including the semiconductor unit according to embodiments of the disclosure are now described with reference to FIGS. 1 to 25. The embodiments of the disclosure are described in the following order. The disclosure should not be limited to the following Examples.

1. First Embodiment: Capacitive device including a first capacitive element of an n-channel MOSFET type and a second capacitive element of a p-type storage capacitor type.

2. Second Embodiment: Capacitive device including a first capacitive element of a p-channel MOSFET type and a second capacitive element of an n-type storage capacitor type.

3. Third Embodiment: Capacitive device including a first capacitive element of an n-channel MOSFET type, a second capacitive element of a p-type storage capacitor type, and a third capacitive element of an n-type storage capacitor type.

4. Fourth Embodiment: Capacitive device including a first capacitive element of a p-channel MOSFET type, a second capacitive element of an n-type storage capacitor type, and a third capacitive element of a p-type storage capacitor type.

5. Fifth Embodiment: Example of a capacitive device including two second capacitive elements.

6. Sixth Embodiment: Example of a capacitive device having a gate insulating film having different thicknesses.

7. Seventh Embodiment: Example of a capacitive device including an inter-wiring capacitive element.

8. Eighth Embodiment: Example of a capacitive device including a lower well region.

9. Ninth Embodiment: Example of a capacitive device having no element separation section.

10. Tenth Embodiment: Semiconductor unit including a decoupling capacitor.

11. Eleventh Embodiment: Semiconductor unit including a holding capacitor.

### 1. First Embodiment

### Capacitive Device Including a First Capacitive Element of an n-Channel MOSFET Type and a Second Capacitive Element of a p-Type Storage Capacitor Type

FIG. 1 illustrates a schematic sectional configuration of a capacitive device 1 according to a first embodiment of the disclosure. As illustrated in FIG. 1, the capacitive device 1 of the first embodiment includes a substrate 2, a first capacitive element 4, a second capacitive element 3, and an element separation section 19 that are provided in the substrate 2, and includes a first wiring 15 and a second wiring 16 supplying electric potential to the first capacitive element 4 and the second capacitive element 3, respectively.

The substrate 2 is configured of a semiconductor substrate of a first conduction type (a p type in the first embodiment). The first capacitive element 4 and the second capacitive element 3 are provided in regions close to the surface of the substrate 2.

The first capacitive element 4 is configured of a first well region 8 formed of a p-type impurity layer provided from the surface to a predetermined depth of the substrate 2, a first gate electrode 11, and two first semiconductor layers 9 of a second conduction type (an n type in the first embodiment) provided in the first well region 8.

The first gate electrode 11 is formed of polysilicon doped with an n-type impurity, and is provided on the substrate 2 with a gate insulating film 12 formed of a silicon oxide film therebetween. Although polysilicon is used as a material for formation of the first gate electrode 11 in the first embodiment, this is not limitative. The first gate electrode 11 may be formed of a metal material such as Al, Ti, TiN, W, Au, and Pt. In addition, although the gate insulating film 12 is formed of the silicon oxide film in the first embodiment, this is not limitative. The gate insulating film 12 may be formed of another insulating material such as SiN, Si₃N₄, HfO₂, HfSiON, HfAlON, ZrO₂, and TiO₂ in addition to SiO₂. Moreover, the gate insulating film 12 may be formed of a ferroelectric material called High-K material.

The two first semiconductor layers 9 are provided in regions close to the surface of the substrate 2, the regions interposing a region corresponding to the first gate electrode 11 therebetween. The two first semiconductor layers 9 may be formed by ion implantation in a self-aligned manner with the first gate electrode 11 as a mask after formation of the first gate electrode 11. Hence, the position of an end of each of the first semiconductor layers 9, which are formed at respective sides of the first gate electrode 11, coincides with the position of an end of the first gate electrode 11.

As described above, the first capacitive element 4 includes the first well region 8 formed of the p-type impurity layer, and the first semiconductor layer 9 formed of the n-type impurity layer. Hence, the first capacitive element 4 has a configuration similar to that of an n-channel MOSFET.

The second capacitive element 3 includes a second well region 5 formed of a p-type impurity layer provided from the surface to a predetermined depth of the substrate 2, a second gate electrode 7, and two second semiconductor layers 6 each formed of a p-type impurity layer provided in the second well region 5. The impurity concentration of the p-type impurity layer configuring the second semiconductor layers 6 is higher than that of the p-type impurity layer configuring the second well region 5.

The second gate electrode 7 is formed of polysilicon doped with a p-type impurity, and is provided on the substrate 2 with a gate insulating film 12 formed of, for example, a silicon oxide film therebetween. Although polysilicon is used as a material for formation of the second gate electrode 7 in the first embodiment, the material is not limited thereto. The second gate electrode 7 may be formed of a material similar to the above-described material for formation of the first gate electrode 11.

The two second semiconductor layers 6 are provided in regions close to the surface of the substrate 2 at the respective two sides of the second gate electrode 7. The two second semiconductor layers 6 may be formed by ion implantation in a self-aligned manner with the second gate electrode 7 as a mask after formation of the second gate electrode 7. Hence, each second semiconductor layer 6, which is formed at the side of the second gate electrode 7, has an end corresponding to an end of the second gate electrode 7.

As described above, in the second capacitive element 3, the second semiconductor layers 6 have the same conduction type as that of the second well region 5 in which the second semiconductor layers 6 are to be formed, and thus the two second semiconductor layers 6 are continuously short-circuited to each other. According to such a configuration, the second capacitive element 3 is of a p-type storage capacitor type.

The element separation section 19 is provided to define the first well region 8 and the second well region 5 so that the first capacitive element 4 is electrically isolated from the adjacent second capacitive element 3. In the first embodiment, the element separation section 19 is formed by a shallow-trench-isolation (STI) process where an insulator is filled in a trench provided from the surface to a predetermined depth of the substrate 2.

The first wiring 15 is connected to the first gate electrode 11, the second gate electrode 7, and a first electrode 13 from which a predetermined electric potential is supplied. A predetermined voltage is supplied from the first electrode 13 to the first and second gate electrodes 11 and 7 through the first wiring 15. The second wiring 16 is connected to the two first semiconductor layers 9, the two second semiconductor layers 6, and a second electrode 14 from which a predetermined electric potential is supplied. A predetermined voltage is supplied from the second electrode 14 to the first and second semiconductor layers 9 and 6 through the second wiring 16. In the first embodiment, the first and second capacitive elements 4 and 3 are connected in parallel between the first and second electrodes 13 and 14.

FIG. 2 illustrates a planar layout of the capacitive device 1 of the first embodiment. As illustrated in FIG. 2, the first and second well regions 8 and 5 are each formed into a rectangular shape, and are each enclosed by the element separation section 19 for electrical isolation. The first gate electrode 11 is provided to extend in one direction in a central region of the first well region 8, and the second gate electrode 7 is provided to extend in the same direction as the extending direction of the first gate electrode 11 in a central region of the second well region 5.

The first and second wirings 15 and 16 are each provided on the substrate 2, in which the first and second capacitive elements 4 and 3 are provided, with an undepicted oxide film therebetween. As illustrated in FIG. 2, the first wiring 15 is provided to extend in a direction orthogonal to a major axis direction of each of the first and second gate electrodes 11 and 7 while spanning ends of the first and second gate electrodes 11 and 7 formed in parallel. The first wiring 15 is connected to the first gate electrode 11 via a contact 17 at an overlapping position with the first gate electrode 11, and is connected to the second gate electrode 7 via another contact 17 at an overlapping position with the second gate electrode 7.

The second wiring 16 is configured of four branch lines 16a provided to extend over the two first semiconductor layers 9 and the two second semiconductor layers 6, and a main line 16b provided to connect the branch lines 16a to one another. Each of the branch lines 16a is provided to extend in a direction parallel to the major axis direction of each of the first and second gate electrodes 11 and 7, and is electrically connected to a corresponding first or second semiconductor layer 9 or 6 via a contact 18. The main line 16b is provided to extend in a direction perpendicular to the extending direction of the branch line 16a. The main line 16b is provided in connection to the ends of the four branch lines 16a.

In the first embodiment, the first wiring 15 and the main line 16b of the second wiring 16 are disposed at positions opposed to each other with the first and second well regions 8 and 5 therebetween. According to such a layout, the first wiring 15 and the second wiring 16 are disposed at certain positions on the substrate 2 so as to be kept from overlapping. As a result, the first and second wirings 15 and 16 are allowed to be provided in the same wiring layer.

In the above configuration, the first capacitive element 4 has a capacitance formed between the first gate electrode 11 connected to the first electrode 13 and the first semiconductor layer 9 connected to the second electrode 14. The second capacitive element 3 has a capacitance formed between the second gate electrode 7 connected to the first electrode 13 and the second semiconductor layer 6 connected to the second electrode 14. The first capacitive element 4 and the second capacitive element 3 are wired into parallel connection; hence, the capacitive device 1 of the first embodiment has a composite capacitance value corresponding to the sum of the capacitance value of the first capacitive element 4 and the capacitance value of the second capacitive element 3.

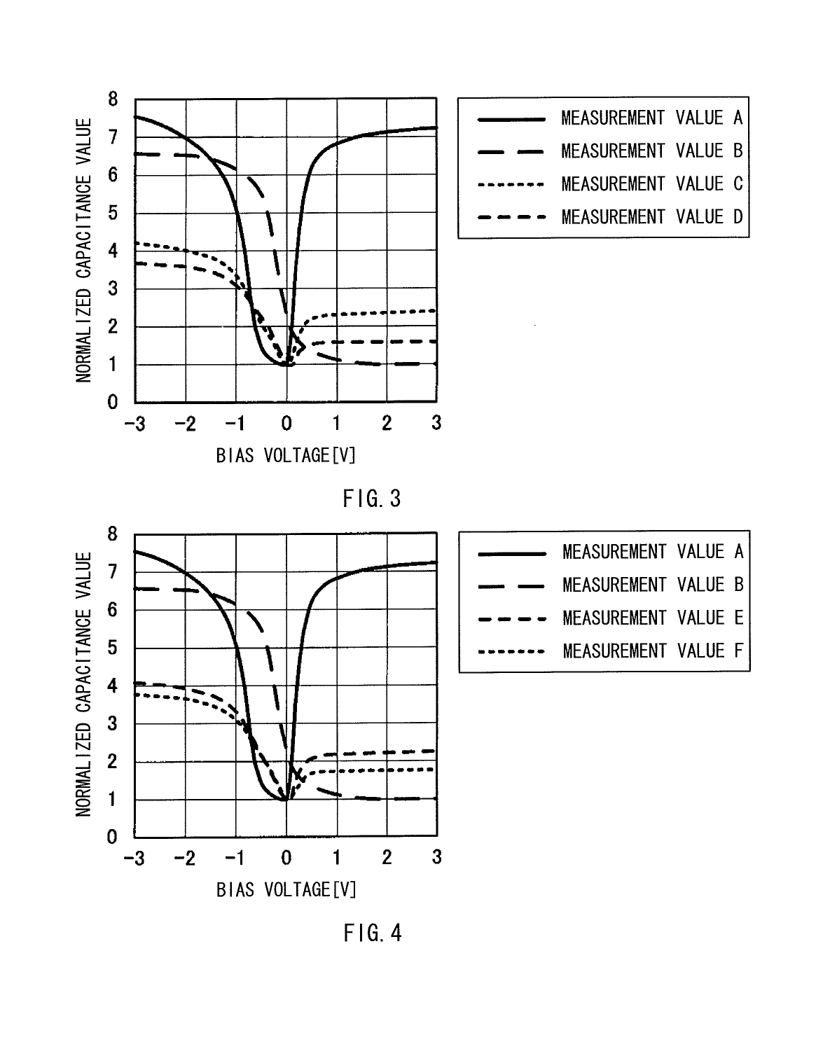

FIGS. 3 and 4 each illustrate C-V characteristics of each of the first and second capacitive elements 4 and 3, and C-V characteristics of the capacitive device 1 of the first embodiment including the first and second capacitive elements 4 and 3 connected in parallel. In FIGS. 3 and 4, the horizontal axis indicates a bias voltage applied between the first electrode 13 and the second electrode 14, and the vertical axis indicates a capacitance value (normalized capacitance value) normalized with a capacitance value at a bias voltage of 0 V. In the measurement of the C-V characteristics, the capacitance value is measured while the bias voltage applied to the first electrode 13 is varied with the second electrode 14 at a ground potential.

A measurement value A in FIGS. 3 and 4 represents a result of the measurement of only the capacitance value of the first capacitive element 4. A measurement value B in FIGS. 3 and 4 represents a result of the measurement of only the capacitance value of the second capacitive element 3. A measurement value C in FIG. 3 represents a result of the measurement of the capacitance value of the capacitive device 1 including the first and second capacitive elements 4 and 3 connected in parallel. A measurement value D in FIG. 3 represents a result of the measurement of the capacitance value of the capacitive device 1 including the first and second capacitive elements 4 and 3 connected in parallel in the case where only the gate area of the second gate electrode 7 is two times larger than that in the measurement of the value C.

A measurement value E in FIG. 4 represents a result of the measurement of the capacitance value of the capacitive device 1 including the first and second capacitive elements 4 and 3 connected in parallel in the case where only the gate area of the first gate electrode 11 is 0.9 times larger than that in the measurement of the value C. A measurement value F in FIG. 4 represents a result of the measurement of the capacitance value of the capacitive device 1 including the first and second capacitive elements 4 and 3 connected in parallel in the case where only the gate area of the first gate electrode 11 is 0.6 times larger than that in the measurement of the value C.

FIG. 3 shows that the capacitance value (the measurement value C) of the capacitive device 1 of the first embodiment less varies with variations in bias voltage than the capacitance value (the measurement value A or B) of the first or second capacitive element 4 or 3 being singly used. In other words, the capacitance value of the capacitive device 1 of the first embodiment has a low, or flat, bias dependence compared with that of each of the first and second capacitive elements 4 and 3.

In addition, the capacitance value of the capacitive device 1 of the first embodiment significantly less varies with variations in bias voltage particularly in a positive bias region. This reveals that the capacitive device 1 of the first embodiment has a greatly reduced bias dependence in the positive bias region compared with a case where the first and second capacitive elements 4 and 3 are each singly used.

In addition, a comparison between the measurement value C and the measurement value D shows that the capacitance value of the measurement value D has a lower bias dependence. This reveals that the bias dependence of the capacitance value is further reduced through an increase in gate area of the second gate electrode 7 configuring the second capacitance element 3.

Furthermore, a comparison between the measurement value E and the measurement value F shows that a capacitance value represented by the measurement value F has a lower bias dependence. This reveals that the bias dependence of the capacitance value is further reduced through a decrease in gate area of the first gate electrode 11 configuring the first capacitance element 4.

As described above, the capacitive device 1 of the first embodiment includes the first and second capacitive elements 4 and 3 connected in parallel, and thus has a reduced bias dependence of the capacitance value compared with a case where the first and second capacitive elements 4 and 3 are each singly used. In addition, the bias dependence of the capacitance value is further reduced through adjustment of a ratio of gate area between the first gate electrode 11 and the second gate electrode 7.

The 1.8 V-series MOSFET incorporated in a common CMOS-LSI has a gate insulating film configured of an oxide film formed of SiO₂ of 4 nm in thickness, and has a gate capacitance of about 10 fF/μm² at a gate voltage of power voltage VDD. The first capacitive element 4 and the second capacitive element 3 of the capacitive device 1 of the first embodiment may each include the same gate insulating film as that of the 1.8 V-series MOSFET, and may be formed to have the same gate area. In such a case, if 1.8 V is applied between the electrodes, the first capacitive element 4 has a capacitance value of about 10 fF/μm² similar to that of the MOSFET. On the other hand, the second capacitive element 3 has a capacitance value of about 1.5 fF/μm². Consequently, if 1.8 V is applied between the electrodes, the composite capacitance of the first capacitive element 4 and the second capacitive element 3 is about 5.8 fF/μm², which is obtained by dividing the sum of the capacitance values of the respective capacitive elements 4 and 3 by the gate area. In this way, the capacitive device 1 of the first embodiment includes the first and second capacitive elements 4 and 3 connected in parallel, and thus has a decreased capacitance value per device area compared with a case where the first and second capacitive elements 4 and 3 are each singly used.

In the typical inter-wiring capacitive element, which has a capacitance formed between lines in a wiring layer provided on a semiconductor substrate, however, even if four-layer wiring is used with, for example, a 65 nm-generation design rule, a capacitance value per unit area is as low as about 1.5 fF/μm². Hence, the capacitive device 1 of the first embodiment has a sufficiently large capacitance compared with such a capacitive device with the inter-wiring capacitance.

The first capacitive element 4 and the second capacitive element 3 configuring the capacitive device 1 of the first embodiment each have a device structure similar to a structure of a common n-channel or p-channel MOSFET. Hence, the first capacitive element 4 and the second capacitive element 3 in the first embodiment may be incorporated in a CMOS capacitive device incorporating a common MOSFET without any additional step.

Furthermore, a semiconductor unit including a typical complementary MOS capacitive device using an n-type storage capacitor element and a p-type storage capacitor element (see JP-A-2005-197396) is necessary to line up both an n-type storage capacitor element and a p-type storage capacitor element as available elements. This results in a complicated manufacturing line and an increase in number of steps. In contrast, the capacitive device 1 of the first embodiment includes the first capacitive element 4 having the same structure as that of a common n-type MOSFET. As a result, the capacitive device 1 of the first embodiment may be manufactured without an increase in manufacturing cost, as long as at least a p-type storage capacitor element (corresponding to the second capacitive element 3) is lined up as an available element in an intended semiconductor process.

Although the first embodiment has been described with a capacitance value in the case where the bias voltage of the first electrode 13 is varied positively and negatively with the second electrode 14 at 0 V, the bias voltage of the second electrode 14 may be varied positively and negatively with the first electrode 13 at 0 V.

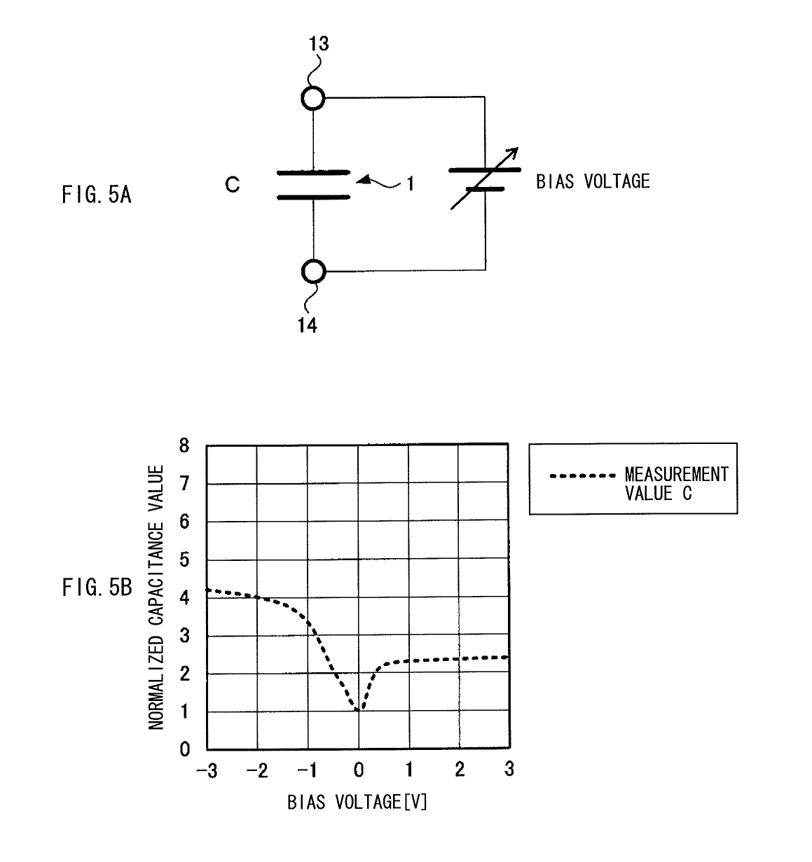

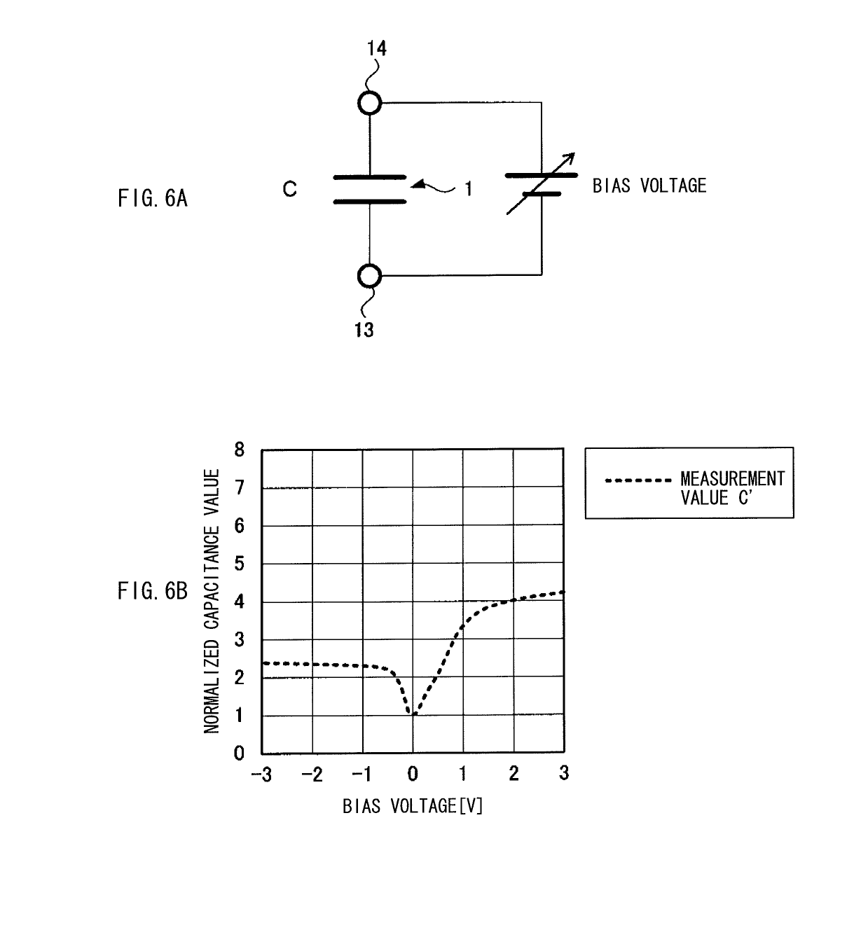

FIG. 5A illustrates an equivalent circuit diagram of the capacitive device 1 of the first embodiment in the case where the bias voltage of the first electrode 13 is varied positively and negatively with the second electrode 14 at 0 V. FIG. 5B illustrates C-V characteristics in such a case. FIG. 6A illustrates an equivalent circuit diagram of the capacitive device 1 of the first embodiment in the case where the bias voltage of the second electrode 14 is varied positively and negatively with the first electrode 13 at 0 V. FIG. 6B illustrates C-V characteristics in such a case. The measurement value C′ in FIG. 5B corresponds to the measurement value C in FIG. 3. The measurement value C in FIG. 6B corresponds to the capacitance value of the capacitive device 1 in the equivalent circuit of FIG. 6A.

As shown in FIGS. 5B and 6B, the electrodes are reversed such that each electrode receives a bias voltage having an opposite polarity, thereby the C-V characteristics are mirror-inverted with respect to the vertical axis. Specifically, a polarity of each of the first and second electrodes 13 and 14 is reversed, and thus polar behavior of the bias dependence of the capacitance value is inverted. Consequently, the capacitive device 1 of the first embodiment reduces bias dependence not only in a positive bias region but also in a negative bias region through reversing a polarity of a voltage applied to each of the first and second electrodes 13 and 14.

Generally, in the case where a MOS capacitive device is used as a holding capacitor used for, for example, a comparator circuit, bias dependence of a capacitance value is not necessary to be flattened in both positive and negative regions for a bias voltage applied between the electrodes of the capacitive device. Hence, as shown in the capacitive device 1 of the first embodiment, if the bias dependence of a capacitance value is reduced only in one polarity region, the capacitive device may be sufficiently used for various integrated circuits such as a comparator circuit.

### 2. Second Embodiment

### Capacitive Device Including a First Capacitive Element of a p-Channel MOSFET Type and a Second Capacitive Element of an n-Type Storage Capacitor Type

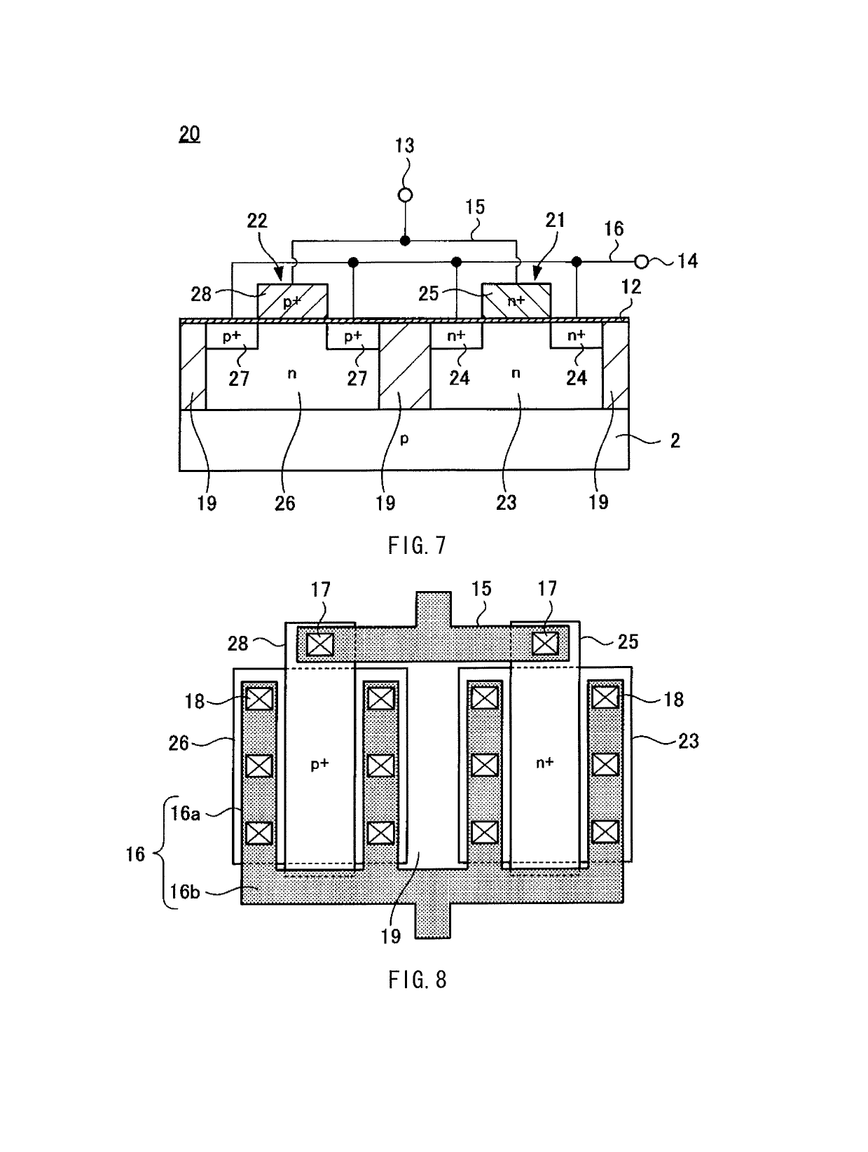

A capacitive device according to a second embodiment of the disclosure is now described. FIG. 7 illustrates a schematic sectional configuration of a capacitive device 20 according to the second embodiment. In FIG. 7, portions corresponding to those in FIG. 1 are designated by the same numerals, and duplicated description thereof is omitted.

As illustrated in FIG. 7, the capacitive device 20 of the second embodiment includes a substrate 2, a first capacitive element 22, a second capacitive element 21, and an element separation section 19 that are provided in the substrate 2, and a first wiring 15 and a second wiring 16.

The first capacitive element 22 is configured of a first well region 26, a first gate electrode 28, and two first semiconductor layers 27. The first well region 26 is formed of an n-type impurity layer provided from the surface to a predetermined depth of the substrate 2, and the two first semiconductor layers 27 are each formed of a p-type impurity layer provided in the first well region 26

The first gate electrode 28 includes polysilicon doped with a p-type impurity, and is provided on the substrate 2 with a gate insulating film 12 formed of a silicon oxide film therebetween. The two first semiconductor layers 27 are provided in regions close to the surface of the substrate 2, the regions interposing a region corresponding to the first gate electrode 28 therebetween. The two first semiconductor layers 27 may be formed by ion implantation in a self-aligned manner with the first gate electrode 28 as a mask after formation of the first gate electrode 28. Hence, each first semiconductor layer 27, which is formed at the side of the first gate electrode 28, has an end corresponding to an end of the first gate electrode 28.

As described above, the first capacitive element 22 includes the first well region 26 configured of the n-type impurity layer, and the first semiconductor layer 27 formed of the p-type impurity layer. Hence, the first capacitive element 22 has a configuration similar to that of a p-channel MOSFET.

The second capacitive element 21 includes a second well region 23 formed of an n-type impurity layer provided from the surface to a predetermined depth of the substrate 2, a second gate electrode 25, and two second semiconductor layers 24 each formed of an n-type impurity layer provided in the second well region 23. The impurity concentration of the n-type impurity layer configuring the second semiconductor layers 24 is higher than that of the n-type impurity layer configuring the second well region 23.

The second gate electrode 25 is formed of polysilicon doped with an n-type impurity, and is provided on the substrate 2 with a gate insulating film 12 therebetween. The two second semiconductor layers 24 are provided in regions close to the surface of the substrate 2, the regions interposing a region corresponding to the second gate electrode 25 therebetween. The two second semiconductor layers 24 may be formed by ion implantation in a self-aligned manner with the second gate electrode 25 as a mask after formation of the second gate electrode 25. Hence, each second semiconductor layer 24, which is formed at the side of the second gate electrode 25, has an end corresponding to an end of the second gate electrode 25.

As described above, in the second capacitive element 21, the second semiconductor layers 24 each have the same conduction type as that of the second well region 23 in which the second semiconductor layers 24 are to be formed, and thus the two second semiconductor layers 24 are continuously short-circuited to each other. According to such a configuration, the second capacitive element 21 is of an n-type storage capacitor type.

The first wiring 15 is connected to the first gate electrode 28, the second gate electrode 25, and a first electrode 13 from which a predetermined electric potential is supplied. A predetermined voltage is supplied from the first electrode 13 to the first and second gate electrodes 28 and 25 through the first wiring 15.

The second wiring 16 is connected to the two first semiconductor layers 27, the two second semiconductor layers 24, and a second electrode 14 from which a predetermined electric potential is supplied. A predetermined voltage is supplied from the second electrode 14 to the first and second semiconductor layers 27 and 24 through the second wiring 16.

In the second embodiment, the first and second capacitive elements 22 and 21 are connected in parallel between the first and second electrodes 13 and 14.

FIG. 8 illustrates a planar layout of the capacitive device 20 of the second embodiment. As illustrated in FIG. 8, the first and second well regions 26 and 23 are each formed into a rectangular shape, and are each enclosed by the element separation section 19 for electrical isolation. The first gate electrode 28 is provided to extend in one direction in a central region of the first well region 26, and the second gate electrode 25 is provided to extend in the same direction as the extending direction of the first gate electrode 28 in a central region of the second well region 23.

The first and second wirings 15 and 16 are each provided on the substrate 2 in the same layout as in the first embodiment. The first wiring 15 is connected to the first gate electrode 28 and the second gate electrode 25 via contacts 17. The second wiring 16 is connected to the first semiconductor layer 27 and the second semiconductor layer 24 via contacts 18.

In the second embodiment, since the first well region 26 in which the first capacitive element 22 is to be formed is electrically floated, a well tap (not shown) is provided to maintain the electrical potential of the first well region 26 to a predetermined potential, i.e., to electrically fix the well region 26.

In the above configuration, the first capacitive element 22 has a capacitance formed between the first gate electrode 28 connected to the first electrode 13 and the first semiconductor layer 27 connected to the second electrode 14. The second capacitive element 21 has a capacitance formed between the second gate electrode 25 connected to the first electrode 13 and the second semiconductor layer 24 connected to the second electrode 14. The first capacitive element 22 and the second capacitive element 21 are wired into parallel connection; hence, the capacitive device 20 of the second embodiment has a composite capacitance value corresponding to the sum of the capacitance value of the first capacitive element 22 and the capacitance value of the second capacitive element 21.

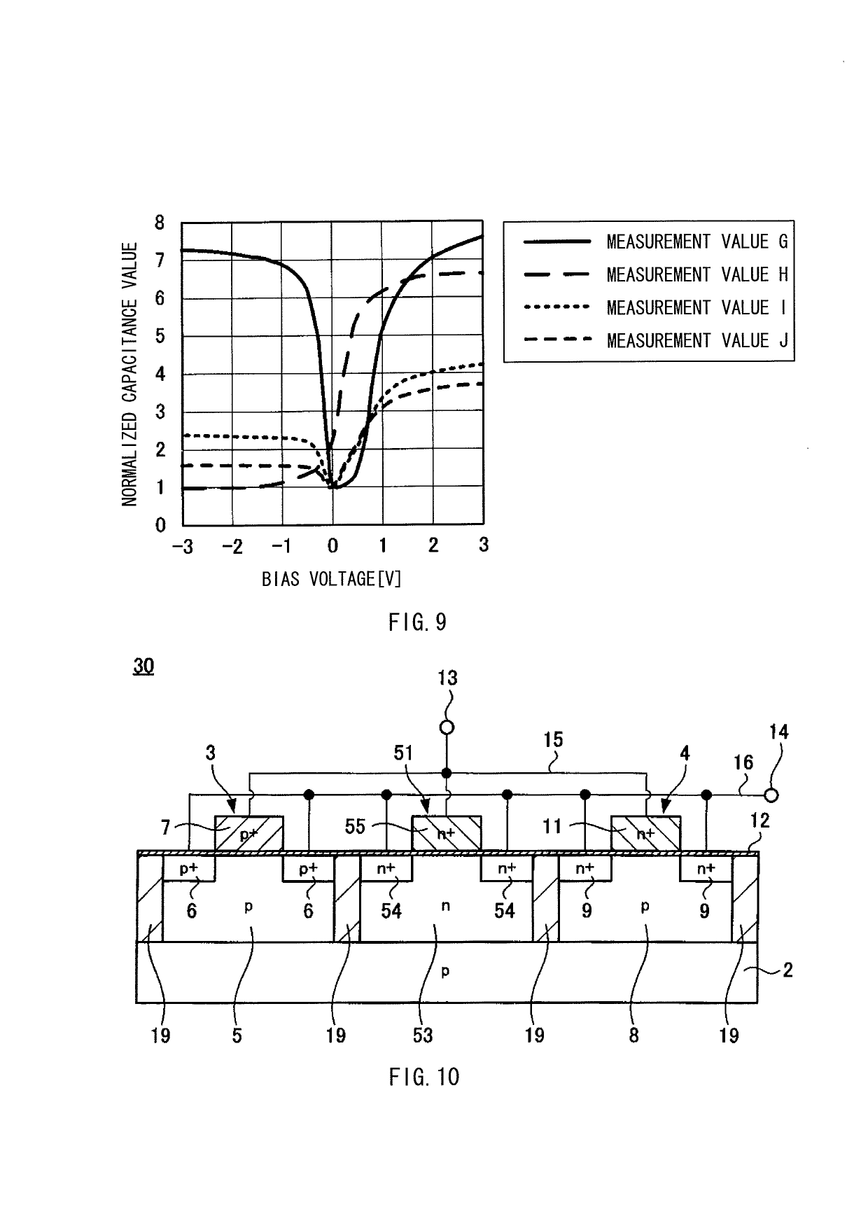

FIG. 9 illustrates C-V characteristics of each of the first and second capacitive elements 22 and 21, and C-V characteristics of the capacitive device 20 of the second embodiment including the first and second capacitive elements 22 and 21 connected in parallel. In FIG. 9, the horizontal axis indicates a bias voltage applied between the first and second electrodes 13 and 14, and the vertical axis indicates a capacitance value normalized with a capacitance value at a bias voltage of 0 V. In the measurement of the C-V characteristic, the capacitance value is measured while the bias voltage applied to the first electrode 13 is varied with the second electrode 14 at a ground potential.

A measurement value G in FIG. 9 represents a result of the measurement of only the capacitance value of the first capacitive element 22. A measurement value H in FIG. 9 represents a result of the measurement of only the capacitance value of the second capacitive element 21. A measurement value I in FIG. 9 represents a result of the measurement of the capacitance value of the capacitive device 20 including the first and second capacitive elements 22 and 21 connected in parallel. A measurement value J in FIG. 9 represents a result of the measurement of the capacitance value of the capacitive device 20 including the first and second capacitive elements 22 and 21 connected in parallel in the case where only the gate area of the second gate electrode 25 is two times larger than that in the measurement of the value I.

FIG. 9 shows that the capacitance value (the measurement value I) of the capacitive device 20 of the second embodiment less varies with variations in bias voltage than the capacitance value (the measurement value G or H) of the first or second capacitive element 22 or 21 being singly used. In other words, the capacitance value of the capacitive device 20 of the second embodiment has a low bias dependence, i.e., has a flat profile compared with that of each of the first and second capacitive elements 22 and 21. In the capacitive device 20 of the second embodiment, the capacitance value less varies with variations in bias voltage particularly in a negative bias region, showing a significant reduction in bias dependence in the negative bias region.

In addition, the capacitance value of the measurement value J has a low bias dependence compared with the measurement value I. This reveals that the bias dependence of the capacitance value is further reduced through an increase in gate area of the second gate electrode 25 configuring the second capacitance element 21.

As described above, the capacitive device 20 of the second embodiment also includes the first and second capacitive elements 22 and 21 connected in parallel, and thus has a reduced bias dependence of the capacitance value compared with a case where the first and second capacitive elements 22 and 21 are each singly used. In addition, the bias dependence of the capacitance value is further reduced through adjustment of a ratio of gate area between the first gate electrode 28 and the second gate electrode 25.

In the second embodiment, the bias voltage of the second electrode 14 may be also varied positively and negatively with the first electrode 13 at 0 V, so that the bias dependence is reduced in the positive bias region. In addition, other advantageous effects similar to those in the first embodiment are achieved in the second embodiment.

### 3. Third Embodiment

### Capacitive Device Including a First Capacitive Element of an n-Channel MOSFET Type, a Second Capacitive Element of a p-Type Storage Capacitor Type, and a Third Capacitive Element of an n-Type Storage Capacitor Type

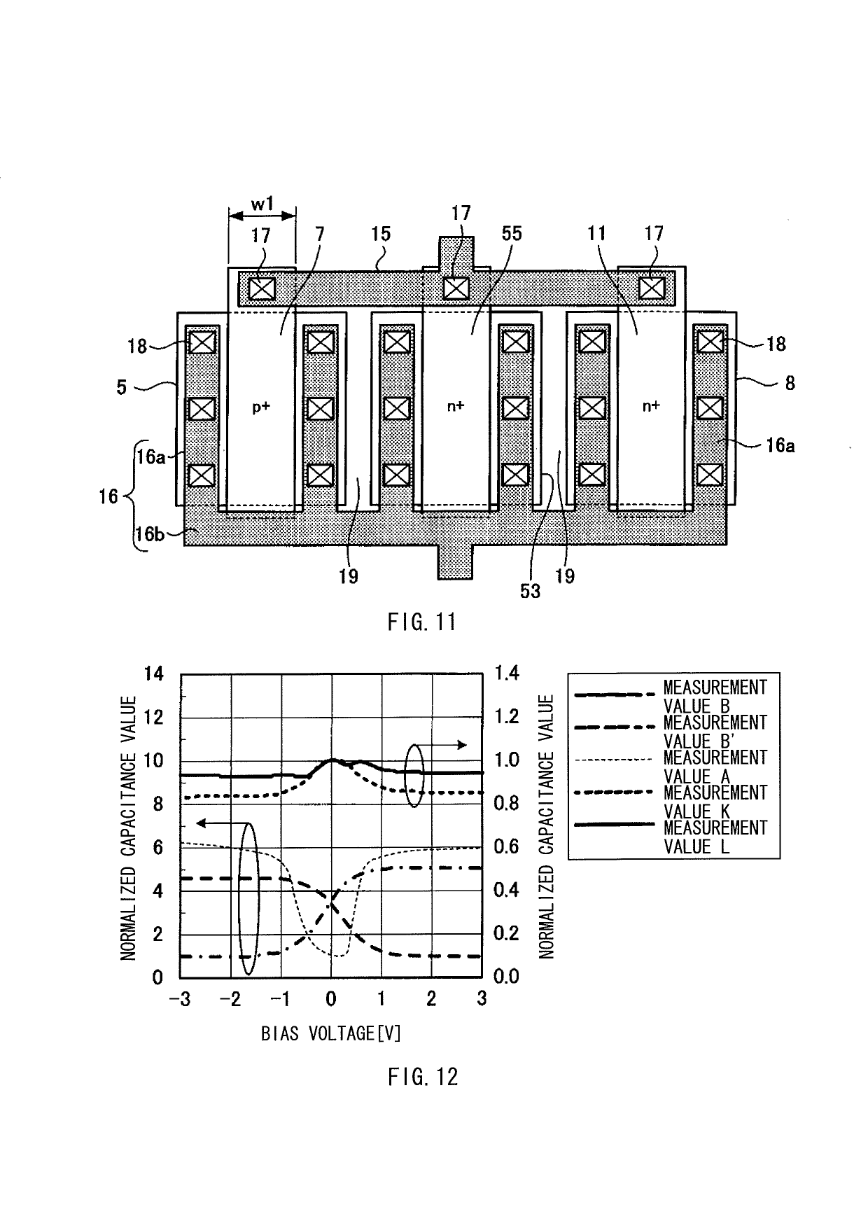

A capacitive device according to a third embodiment of the disclosure is now described. FIG. 10 illustrates a schematic sectional configuration of a capacitive device 30 according to the third embodiment. FIG. 11 illustrates a planar layout of the capacitive device 30 of the third embodiment. In FIGS. 10 and 11, portions corresponding to those in FIGS. 1 and 2 are designated by the same numerals, and duplicated description thereof is omitted. The capacitive device 30 of the third embodiment is different from the capacitive device 1 according to the first embodiment in that a third capacitive device 51 is provided.

As illustrated in FIG. 10, the capacitive device 30 of the third embodiment includes a substrate 2, a first capacitive element 4, a second capacitive element 3, a third capacitive element 51, and element separation sections 19 that are provided in the substrate 2. In addition, the capacitive device 30 of the third embodiment includes a first wiring 15 and a second wiring 16 supplying electric potential to each of the first, second, and third capacitive elements 4, 3, and 51.

The third capacitive element 51 is configured of a third well region 53 formed of an n-type impurity layer provided from the surface to a predetermined depth of the substrate 2, a third gate electrode 55, and two third semiconductor layers 54 each formed of an n-type impurity layer provided in the third well region 53.

The third gate electrode 55 is formed of polysilicon doped with an n-type impurity, and is provided on the substrate 2 with a gate insulating film 12 formed of a silicon oxide film therebetween. The two third semiconductor layers 54 are provided in regions close to the surface of the substrate 2, the regions interposing a region corresponding to the third gate electrode 55 therebetween. The impurity concentration of the third semiconductor layer 54 is higher than that of the n-type impurity layer configuring the third well region 53.

The two third semiconductor layers 54 configuring the third capacitive element 51 may be formed by ion implantation in a self-aligned manner with the third gate electrode 55 as a mask after formation of the third gate electrode 55. Hence, each third semiconductor layer 54, which is formed at the side of the third gate electrode 55, has an end corresponding to an end of the third gate electrode 55.

As described above, in the third capacitive element 51, the third semiconductor layers 54 each have the same conduction type as that of the third well region 53 in which the third semiconductor layers 54 are to be formed, and thus the two third semiconductor layers 54 are continuously short-circuited to each other. According to such a configuration, the third capacitive element 51 is of an n-type storage capacitor type.

The third gate electrode 55 is connected to the first electrode 13 through the first wiring 15 as in the first and second gate electrodes 11 and 7. The third semiconductor layers 54 are connected to the second electrode 14 through the second wiring 16 as in the first and second semiconductor layers 9 and 6. Specifically, in the third embodiment, the first, second, and third capacitive elements 4, 3, and 51 are connected in parallel.

As illustrated in FIG. 11, the third capacitive element 51 is provided, for example, in a region between the first and second capacitive elements 4 and 3, and the third well region 53 is formed into a rectangular shape. In addition, the third well region 53 is also enclosed by the element separation section 19 for electrical isolation from the first and second well regions 8 and 5, as in the first and second well regions 8 and 5. The third gate electrode 55 is provided on the substrate 2 to extend in the same direction as the extending direction of the first and second gate electrodes 11 and 7 in a central region of the third well region 53.

In the third embodiment, the third gate electrode 55 configuring the third capacitive element 51 is connected to the first wiring 15 extending in one direction via a contact 17, as in the first and second capacitive elements 4 and 3. The third semiconductor layers 54 are connected to branch lines 16a extending thereon via contacts 18. Consequently, the third semiconductor layers 54 are connected to the second wiring 16.

FIG. 12 illustrates C-V characteristics of each of the first to third capacitive elements 4, 3, and 51, and C-V characteristics of the capacitive device of the third embodiment including the first to third capacitive elements 4, 3, and 51 connected in parallel. In FIG. 12, the horizontal axis indicates a bias voltage applied between the first and second electrodes 13 and 14, and the vertical axis indicates a capacitance value normalized with a capacitance value at a bias voltage of 0 V. In the measurement of the C-V characteristics, the capacitance value is measured while the bias voltage applied to the first electrode 13 is varied with the second electrode 14 at a ground potential.

The measurement values A and B in FIG. 12 correspond to the measurement values A and B in FIG. 3, respectively. A measurement value B′ in FIG. 12 shows a result of the measurement of only the capacitance value of the third capacitive element 51. A measurement value K in FIG. 12 represents a result of the measurement of the capacitance value of the capacitive device 30 including the second and third capacitive elements 3 and 51 connected in parallel. A measurement value L in FIG. 12 represents a result of the measurement of the capacitance value of the capacitive device 30 of the third embodiment including the first to third capacitive elements 4, 3, and 51 connected in parallel.

The third well region 53 and the third semiconductor layers 54 configuring the third capacitive element 51 each have a conduction type opposite to that of each of the second well region 5 and the second semiconductor layers 6 configuring the second capacitive element 3. As a result, as illustrated in FIG. 12, the C-V characteristic (the measurement value B′) of the third capacitive element 51 is mirror-inverted from the C-V characteristics (the measurement value B) of the second capacitive element 3 with respect to a vertical axis direction. In other words, the bias dependence of the third capacitive element 51 shows a tendency opposite to that of the second capacitive element 3 in each of the positive and negative bias regions.

The capacitance value of the measurement value L has a low bias dependence compared with the measurement value K in each of the positive and negative bias regions. This reveals that the bias dependence is reduced through parallel connection of the first to third capacitive elements 4, 3, and 51 compared with a case of parallel connection of the second and third capacitive elements 3 and 51. Specifically, in the third embodiment, the bias dependence is reduced through parallel connection of the first capacitive element 4 of the n-channel MOSFET type, the second capacitive element 3 of the p-type storage capacitor type, and the third capacitive element 51 of the n-type storage capacitor type.

In a typical semiconductor unit having a complementary MOS capacitive device (see JP-A-2005-197396), the threshold voltage of the capacitive device is necessary to be adjusted independently of the MOSFET integrated therewith in order to further reduce the bias dependence of the capacitance value. This results in a need of an additional ion implantation step to adjust the threshold voltage of the capacitive device, leading to an increase in cost.

In contrast, the capacitive device of the third embodiment has the third capacitive element 51, allowing a further reduction in bias dependence of the capacitance value. In addition, the first to third capacitive elements 4, 3, and 51 may be formed in the same process as that of the p-type or n-type MOSFET to be formed on the same substrate 2, which eliminates the need of any additional step, leading to a reduction in cost.

Furthermore, the third embodiment also reduces the bias dependence of the capacitance value through varying gate area (gate area ratio) between the first, second, and third capacitive elements 4, 3, and 51. In addition, other advantageous effects similar to those in the first embodiment are achieved in the third embodiment.

The 1.8 V-series MOSFET incorporated in a common CMOS-LSI has a gate insulating film configured of an oxide film formed of SiO₂ of 4 nm in thickness, and has a gate capacitance of about 10 fF/μm² at a gate voltage of power voltage VDD. Hence, if each capacitive element includes the same gate insulating film as that of the 1.8 V-series MOSFET, and if 1.8 V is applied between the electrodes, each of the capacitive elements 4 and 51 has a gate capacitance of about 10 fF/μm². On the other hand, if 1.8 V is applied between the electrodes, the capacitive element 3 has a gate capacitance of about 1.5 fF/μm². Consequently, when the first to third capacitive elements 4, 3, and 51 each have the same gate area, the composite capacitance of the first to third capacitive elements 4, 3, and 51 is about 7.2 fF/μm², which is obtained by dividing the sum of the capacitance values of the respective capacitive elements 4, 3, and 51 by the gate area.

In this way, the capacitive device 30 of the third embodiment includes the first to third capacitive elements 4, 3, and 51 connected in parallel, and thus has a decreased capacitance value per device area compared with a case where the first and third capacitive elements 4 and 51 are each singly used.

In the typical inter-wiring capacitive device, which has capacitance formed between lines in a wiring layer provided on a semiconductor substrate, however, even if four-layer wiring is used with, for example, a 65 nm-generation design rule, a capacitance value per unit area is as low as about 1.5 fF/μm². Hence, the capacitive device 30 of the third embodiment has a sufficiently large capacitance compared with such a capacitive device with the inter-wiring capacitance.

### 4. Fourth Embodiment

### Capacitive Device Including a First Capacitive Element of a p-Channel MOSFET Type, a Second Capacitive Element of an n-Type Storage Capacitor Type, and a Third Capacitive Element of a p-Type Storage Capacitor Type

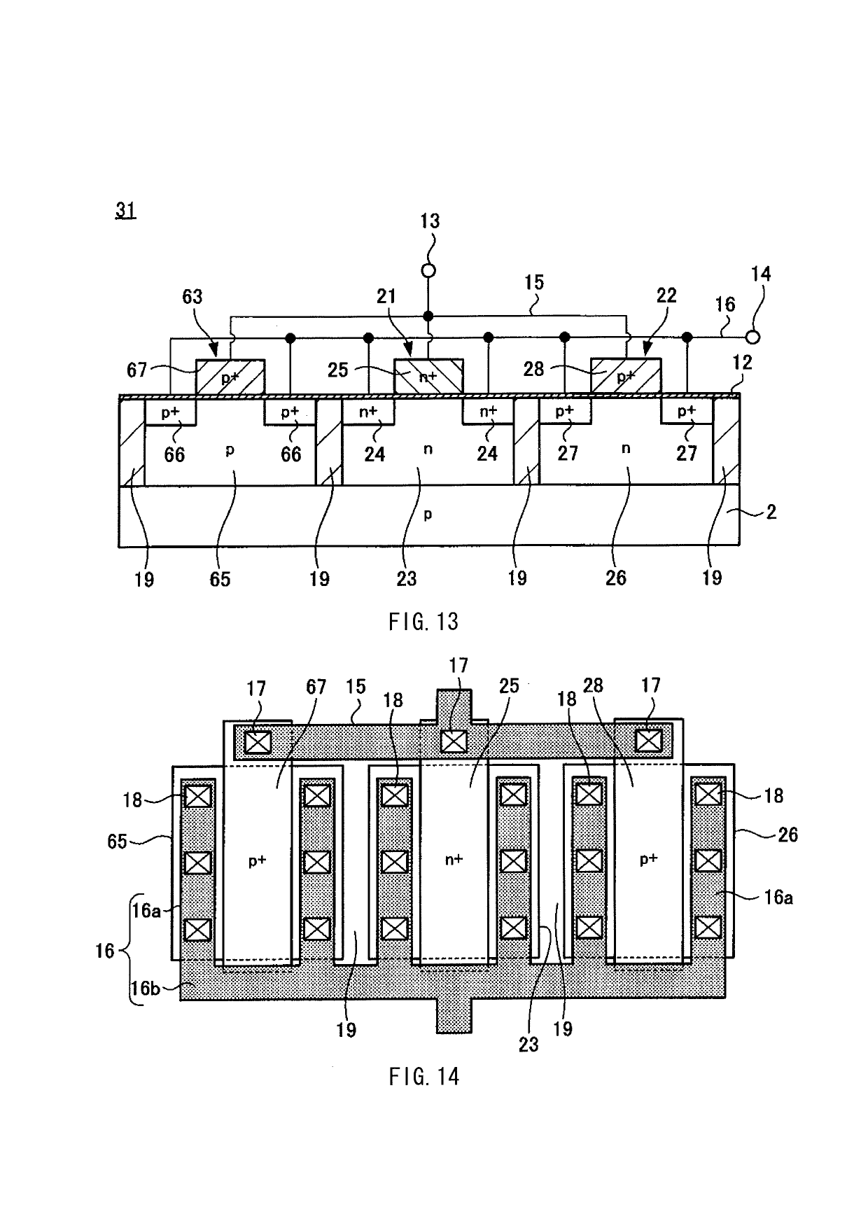

A capacitive device according to a fourth embodiment of the disclosure is now described. FIG. 13 illustrates a schematic sectional configuration of a capacitive device 31 according to the fourth embodiment. FIG. 14 illustrates a planar layout of the capacitive device 31 of the fourth embodiment. In FIGS. 13 and 14, portions corresponding to those in FIGS. 7 and 8 are designated by the same numerals, and duplicated description thereof is omitted. The capacitive device 31 of the fourth embodiment is different from the capacitive device 20 according to the second embodiment in that a third capacitive device 63 is provided.

As illustrated in FIG. 13, the capacitive device 31 of the fourth embodiment includes a substrate 2, a first capacitive element 22, a second capacitive element 21, the third capacitive element 63, and element separation sections 19 that are provided in the substrate 2. In addition, the capacitive device 31 includes a first wiring 15 and a second wiring 16 supplying electric potential to each of the first, second, and third capacitive elements 22, 21, and 63.

The third capacitive element 63 is configured of a third well region 65 formed of a p-type impurity layer provided from the surface to a predetermined depth of the substrate 2, a third gate electrode 67, and two third semiconductor layers 66 each formed of a p-type impurity layer provided in the third well region 65.

The third gate electrode 67 is formed of polysilicon doped with a p-type impurity, and is provided on the substrate 2 with a gate insulating film 12 formed of a silicon oxide film therebetween. The two third semiconductor layers 66 are provided in regions close to the surface of the substrate 2, the regions interposing a region corresponding to the third gate electrode 67 therebetween. The impurity concentration of the third semiconductor layer 66 is higher than that of the p-type impurity layer configuring the third well region 65.

The two third semiconductor layers 66 may be formed by ion implantation in a self-aligned manner with the third gate electrode 67 as a mask after formation of the third gate electrode 67. Hence, each third semiconductor layer 66, which is formed at the side of the third gate electrode 67, has an end corresponding to an end of the third gate electrode 67.

As described above, in the third capacitive element 63, the third semiconductor layer 66 have the same conduction type as that of the third well region 65 in which the third semiconductor layer 66 are to be formed, and thus the two third semiconductor layers 66 are continuously short-circuited to each other. According to such a configuration, the third capacitive element 63 is of a p-type storage capacitor type.

The third gate electrode 67 is connected to the first electrode 13 through the first wiring 15 as in the first and second gate electrodes 28 and 25. The third semiconductor layers 66 are connected to the second electrode 14 through the second wiring 16 as in the first and second semiconductor layers 27 and 24. Specifically, in the fourth embodiment, the first, second, and third capacitive elements 22, 21, and 63 are connected in parallel.

As illustrated in FIG. 14, the third capacitive element 63 is provided, for example, in a region adjacent to the second capacitive element 21, and the third well region 65 is formed into a rectangular shape. In addition, the third well region 65 is also enclosed by the element separation section 19 for electrical isolation from the first and second well regions 26 and 23, as in the first and second well regions 26 and 23. The third gate electrode 67 is provided on the substrate 2 to extend in the same direction as the extending direction of the first and second gate electrodes 28 and 25 in a central region of the third well region 65.

In the fourth embodiment, the third gate electrode 67 is also connected to the first wiring 15 extending in one direction via a contact 17, as in the first and second capacitive elements 22 and 21. The third semiconductor layers 66 are connected to branch lines 16a extending thereon via contacts 18. Consequently, the third semiconductor layers 66 are connected to the second wiring 16.

The third well region 65 and the third semiconductor layers 66 configuring the third capacitive element 63 each have a conduction type opposite to that of each of the second well region 23 and the second semiconductor layers 24 configuring the second capacitive element 21. As a result, the C-V characteristics (not shown) of the third capacitive element 63 is mirror-inverted from the C-V characteristics (the measurement value I) of the second capacitive element 21 shown in FIG. 9 with respect to a vertical axis direction. In the fourth embodiment, the bias dependence is also reduced through parallel connection of the first to third capacitive elements 22, 21, and 63 compared with a case of parallel connection of the second and third capacitive elements 21 and 63. In addition, other advantageous effects similar to those in the third embodiment are achieved in the fourth embodiment.

### 5. Fifth Embodiment

### Example of a Capacitive Device Including Two Second Capacitive Elements

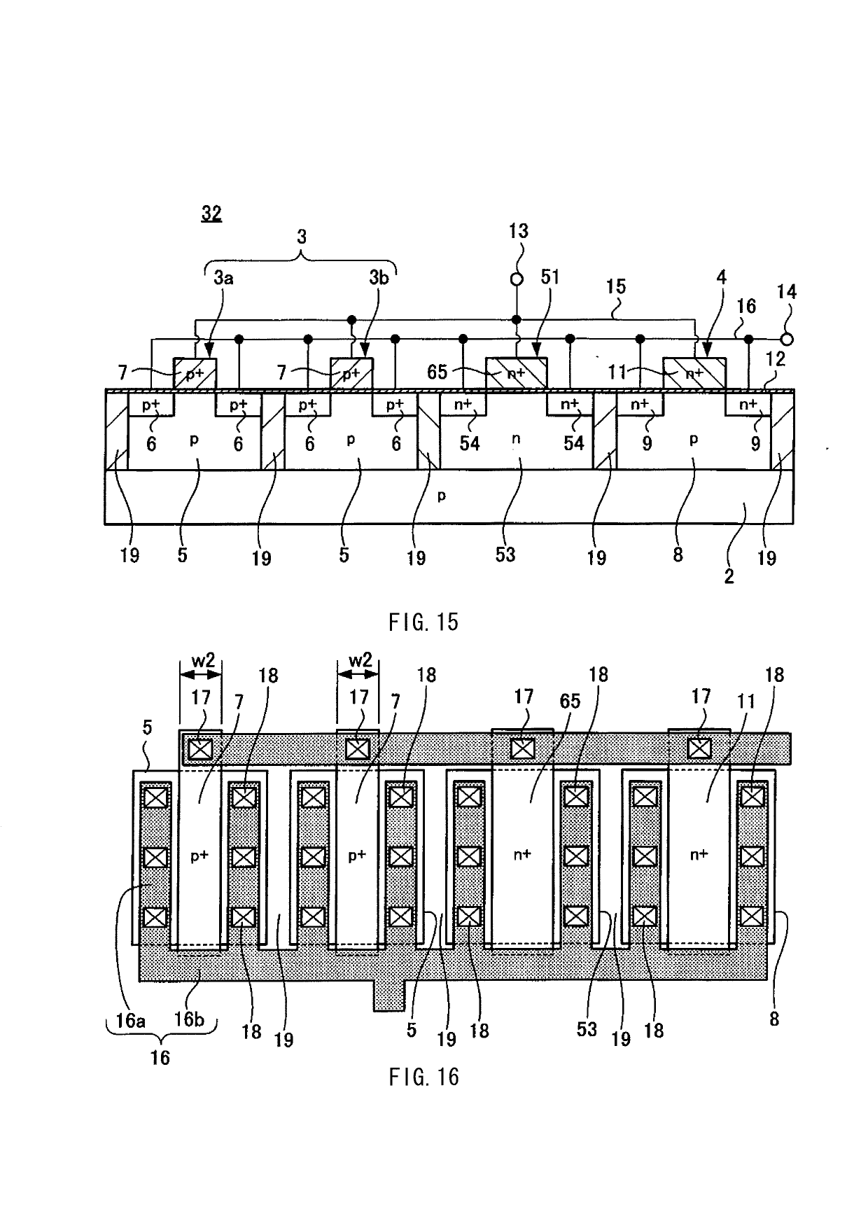

A capacitive device according to a fifth embodiment of the disclosure is now described. FIG. 15 illustrates a schematic sectional configuration of a capacitive device 32 according to the fifth embodiment. FIG. 16 illustrates a planar layout of the capacitive device 32 of the fifth embodiment. In FIGS. 15 and 16, portions corresponding to those in FIGS. 10 and 11 are designated by the same numerals, and duplicated description thereof is omitted. The capacitive device 32 of the fifth embodiment is different from the capacitive device 30 according to the third embodiment in a layout configuration of the second capacitive element 3.

In the fifth embodiment, the second capacitive element 3 is configured of two second capacitive element parts 3a and 3b provided in adjacent regions. The two second capacitive element parts 3a and 3b are each configured of a second well region 5 formed of a p-type impurity layer provided from the surface to a predetermined depth of the substrate 2, a second gate electrode 7, and two second semiconductor layers 6 each formed of a p-type impurity layer provided in the second well region 5. In the fifth embodiment, the second gate electrode 7 configuring each of the second capacitive element parts 3a and 3b has a width w2 approximately half the width w1 (FIG. 11) of the second gate electrode 7 according to the third embodiment.

In the fifth embodiment, as illustrated in FIG. 16, each second gate electrode 7 is connected to the first wiring 15 via a contact 17, and each second semiconductor layer 6 is connected to the second wiring 16 via contacts 18. Consequently, the two second capacitive element parts 3a and 3b, the first capacitive element 4, and the third capacitive element 51 are connected in parallel.

In the fifth embodiment, the second gate electrode 7 configuring each of the second capacitive element parts 3a and 3b has the width w2 approximately half the width w1 of the second gate electrode 7 according to the third embodiment. Thus, although the total capacitance value of the capacitive device 32 is not different from that of the capacitive device 30 according to the third embodiment, the capacitance value of each of the second capacitive element parts 3a and 3b is half the capacitance value of the second capacitive element 3 according to the third embodiment.

In the layout where the second capacitive element 3 is divided into a plurality of (two in the fifth embodiment) second capacitive elements as in the fifth embodiment, the capacitance value is readily varied through varying a pattern of each of the first and second wirings 15 and 16. As a result, even if a specification is modified, or even if there is a need of a modification of a capacitance value of a capacitive device on a circuit in order to optimize the characteristics of a semiconductor unit during development of the semiconductor unit, it is only necessary to modify a wiring mask pattern.

The capacitive device 32 of the fifth embodiment meets a trimming technique such as laser trimming, in which a line is disconnected by laser to electrically separate part of devices connected in parallel for adjustment of device characteristics during a manufacturing process of a semiconductor unit. In addition, other advantageous effects similar to those in the third embodiment are achieved in the fifth embodiment.

### 6. Sixth Embodiment

### Example of a Capacitive Device Having a Gate Insulating Film Having Different Thicknesses

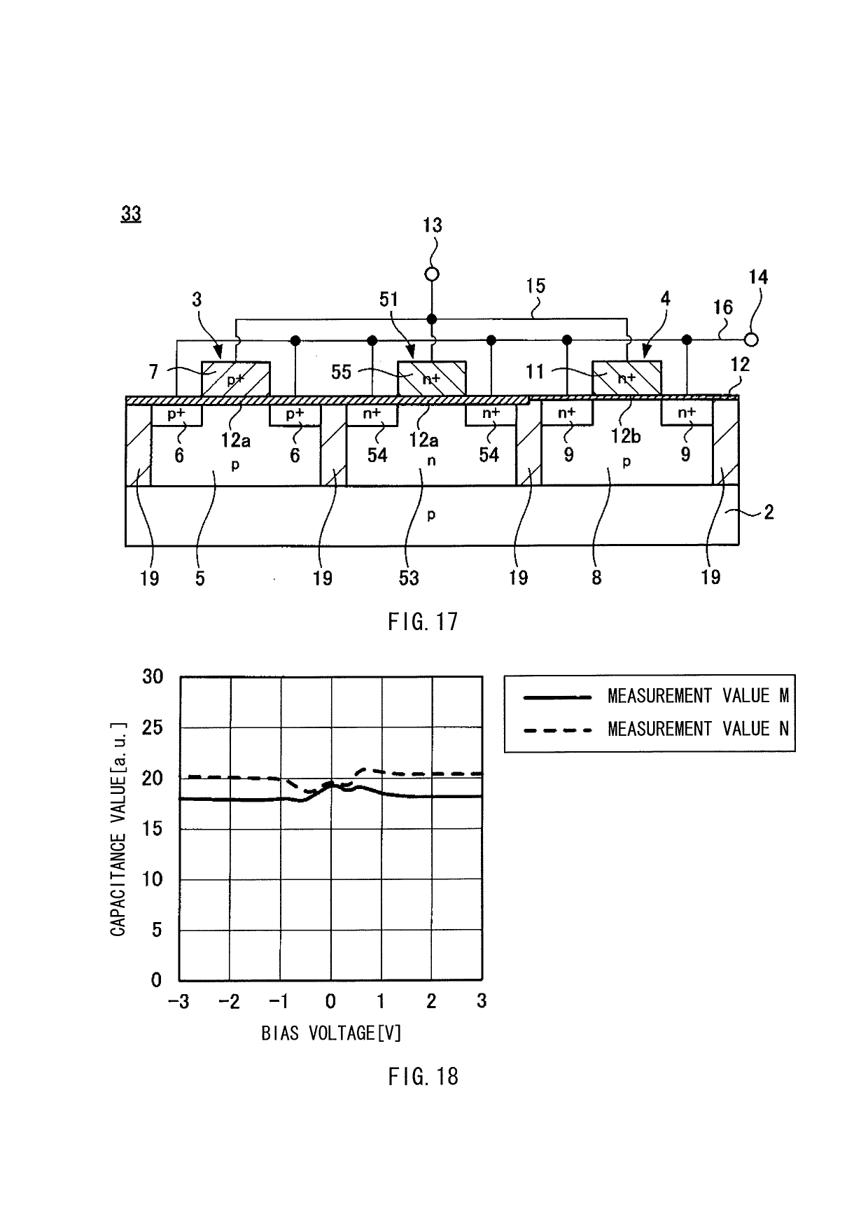

A capacitive device according to a sixth embodiment of the disclosure is now described. FIG. 17 illustrates a schematic sectional configuration of a capacitive device 33 according to the sixth embodiment. In FIG. 17, portions corresponding to those in FIG. 10 are designated by the same numerals, and duplicated description thereof is omitted. The capacitive device 33 of the sixth embodiment is different from the capacitive device 30 according to the third embodiment in thickness of the gate insulating film.

In the sixth embodiment, a gate insulating film 12a configuring a second capacitive element 3 and a third capacitive element 51 has a thickness larger than that of a gate insulating film 12b configuring a first capacitive element 4 by 1.0 nm or more, for example. For example, a gate insulating film optimized for a 1.8 V-series MOSFET is used as the gate insulating film 12a configuring the second and third capacitive elements 3 and 51, and a gate insulating film optimized for a 1.2 V-series MOSFET is used as the gate insulating film 12b configuring the first capacitive element 4.

FIG. 18 illustrates C-V characteristics of the capacitive device 33 of the sixth embodiment, and C-V characteristics of a capacitive device according to a comparative example in which the first to third capacitive elements 4, 3, and 51 connected in parallel are each formed with the gate insulating film optimized for the 1.8 V-series MOSFET. In FIG. 18, a measurement value M represents a measurement result of the capacitance value of the capacitive device according to the comparative example, and a measurement value N represents a measurement result of the capacitance value of the capacitive device 33 of the sixth embodiment.

As illustrated in FIG. 18, the capacitance value (the measurement value N) of the capacitive device 33 of the sixth embodiment is large compared with the capacitance value (the measurement value M) of the capacitive device according to the comparative example exclusively including the gate insulating film optimized for the 1.8 V-series MOSFET. According to the capacitive device 33 of the sixth embodiment, the capacitance value increases by approximately 15% compared with the capacitive device according to the comparative example in terms of devices having the same area. In this way, the capacitive device of the sixth embodiment includes the gate insulating film 12b having a thinner equivalent insulating film (a higher gate capacitance value per unit area) for the first capacitive element 4, thereby achieving an increase in composite capacitance.

In the above example of the sixth embodiment, the gate insulating film (corresponding to the first gate insulating film in the disclosure) configuring the first capacitive element 4 has a thickness different from that of the gate insulating film 12a (corresponding to each of the second and third gate insulating films in the disclosure) configuring the second capacitive element 3 and the third capacitive element 51. The capacitive device of the sixth embodiment, however, should not be limited thereto. For example, all the gate insulating films of the first to third capacitive elements 4, 3, and 51 may have different thicknesses.

### 7. Seventh Embodiment

### Example of a Capacitive Device Having an Inter-Wiring Capacitive Element

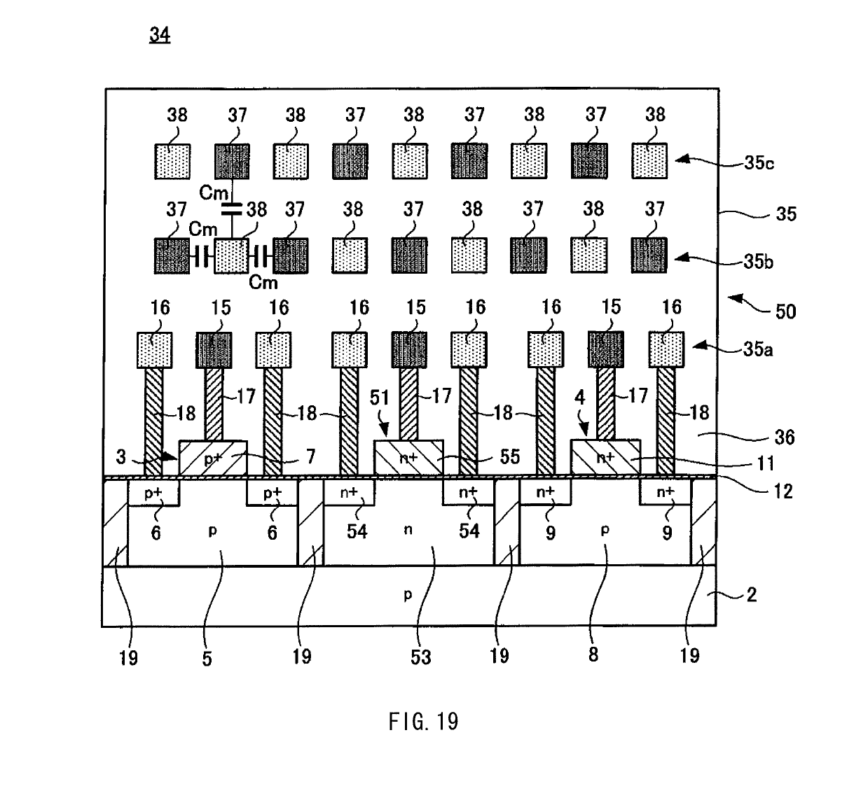

A capacitive device according to a seventh embodiment of the disclosure is now described. FIG. 19 illustrates a schematic sectional configuration of a capacitive device 34 according to the seventh embodiment. In FIG. 19, portions corresponding to those in FIG. 10 are designated by the same numerals, and duplicated description thereof is omitted. The capacitive device 34 of the seventh embodiment is different from the capacitive device 30 according to the third embodiment in that an inter-wiring capacitance is provided.

As illustrated in FIG. 19, in the seventh embodiment, a multilayer wiring layer 35 is provided on a substrate 2, in which multiple (three in the seventh embodiment) wiring sub-layers 35a to 35c are stacked with an inter-layer insulating film 36 therebetween. The first wiring sub-layer 35a provided in a region close to the substrate 2 has a first wiring 15 connected to first to third gate electrodes 11, 7, and 55 via contacts 17, and a second wiring 16 connected to first to third semiconductor layers 9, 6, and 54 via contacts 18. In the second and third wiring sub-layers 35b and 35c, first lines 37 and second lines 38 are alternately disposed in both the in-plane and thickness directions, resulting in formation of inter-wiring capacitance Cm. In other words, the capacitive device of the seventh embodiment has an inter-wiring capacitive element 50 in the multilayer wiring layer 35.

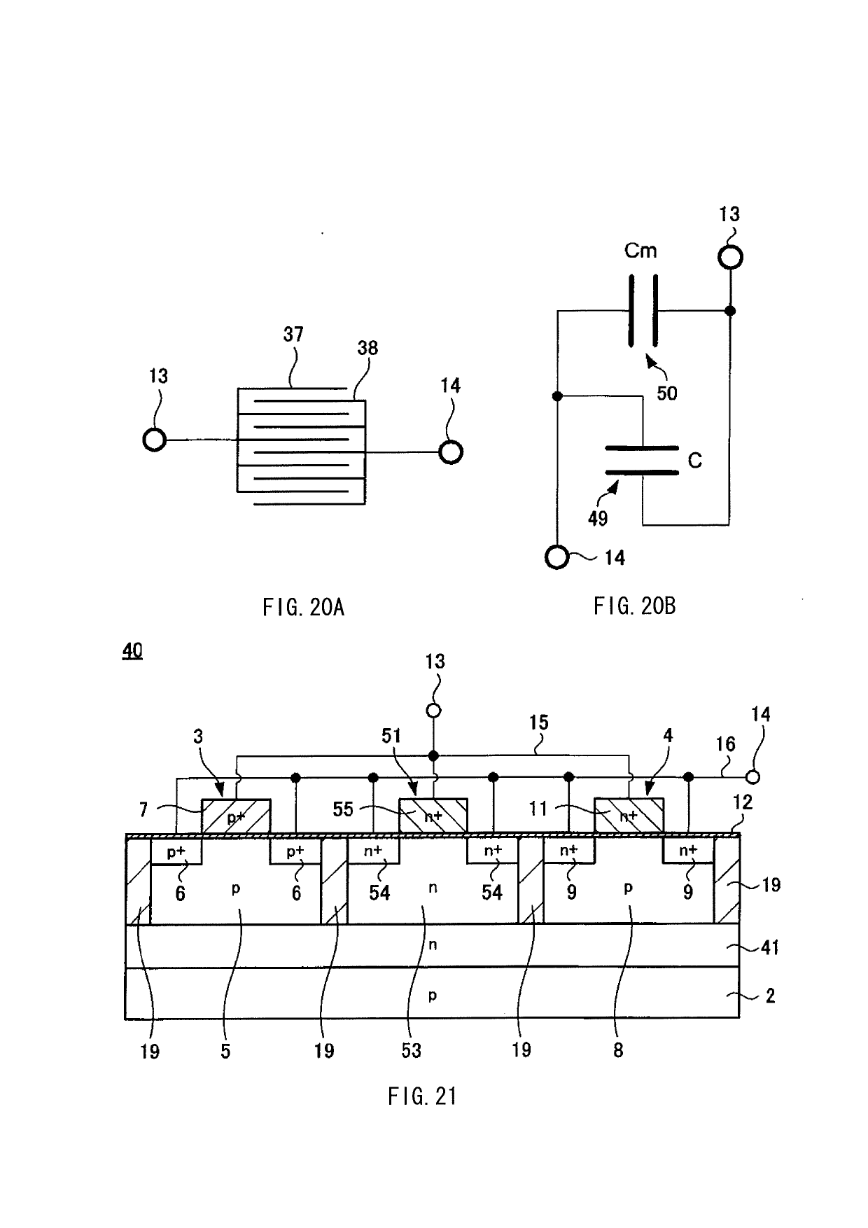

FIG. 20A illustrates a planar configuration of the first lines 37 and the second lines 38 provided in each of the second and third wiring sub-layers 35b and 35c. As illustrated in FIG. 20A, in the second and third wiring sub-layers 35b and 35c, the first lines 37 and the second lines 38 are each formed into a comblike shape and are disposed alternately in an in-plane direction. This causes formation of the inter-wiring capacitance Cm between first and second adjacent lines 37 and 38. In addition, in the seventh embodiment, the second lines 38 in the third layer are disposed on the first lines 37 in the second layer, and the first lines 37 in the third layer are disposed on the second lines 38 in the second layer such that the inter-wiring capacitance Cm is also formed between the second wiring sub-layer 35b and the third wiring sub-layer 35c.

In the seventh embodiment, the inter-wiring capacitive element 50 is also designed such that the first lines 37 are connected to the first electrode 13, and the second lines 38 are connected to the second electrode 14. Thus, as illustrated in FIG. 20B, the inter-wiring capacitive element 50 in the seventh embodiment is connected in parallel to a MOS capacitive device 49 including the first to third capacitive elements 4, 3, and 51.

The capacitive device 34 of the seventh embodiment allows an increase in capacitance value per unit area without increasing device area through parallel connection between the first to third capacitive elements 4, 3, and 51 and the inter-wiring capacitive element 50. In addition, other advantageous effects similar to those in the third embodiment are achieved in the seventh embodiment.

### 8. Eighth Embodiment

### Example of a Capacitive Device with a Lower Well Region

A capacitive device according to an eighth embodiment of the disclosure is now described. FIG. 21 illustrates a schematic sectional configuration of a capacitive device 40 according to the eighth embodiment. In FIG. 21, portions corresponding to those in FIG. 10 are designated by the same numerals, and duplicated description thereof is omitted. The capacitive device 40 of the eighth embodiment is different from the capacitive device 30 according to the third embodiment in that a lower well region 41 is provided.

In the eighth embodiment, the lower well region 41 formed of an n-type impurity layer having a conduction type opposite to that of the substrate 2 is provided below the first to third well regions 8, 5, and 53 configuring the first to third capacitive devices 4, 3, and 51. The lower well region 41 is provided over the entire area in an in-plane direction of the substrate 2 between a p-type region of the substrate 2 and the respective well regions of the first to third capacitive devices 4, 3, and 51.

In the eighth embodiment, the n-type lower well region 41 is provided, so that the well regions 8 and 5 each formed of a p-type impurity layer are electrically isolated from the p-type substrate 2. For example, in the third embodiment, the first and second well regions 8 and 5 each formed of a p-type impurity layer are formed in contact with the p-type substrate 2 into an electrically connected state. Thus, the substrate 2 and the first and second well regions 8 and 5 are exclusively kept at the same potential. In contrast, in the eighth embodiment, the n-type lower well region 41 is provided, so that the first and second well regions 8 and 5 are electrically not connected from the p-type substrate 2, thereby allowing the first and second well regions 8 and 5 to be set to a potential different from that of the substrate 2. In addition, other advantageous effects similar to those in the third embodiment are achieved in the eighth embodiment.

Although the lower well region 41 is provided over the entire area in an in-plane direction of the substrate 2 in the example of the eighth embodiment, the lower well region 41 may be provided only below the first well region 8 and the second well region 5, for example. In other words, the lower well region 41 may be provided only in a necessary portion.

### 9. Ninth Embodiment

### Example of a Capacitive Device Having No Element Separation Section)

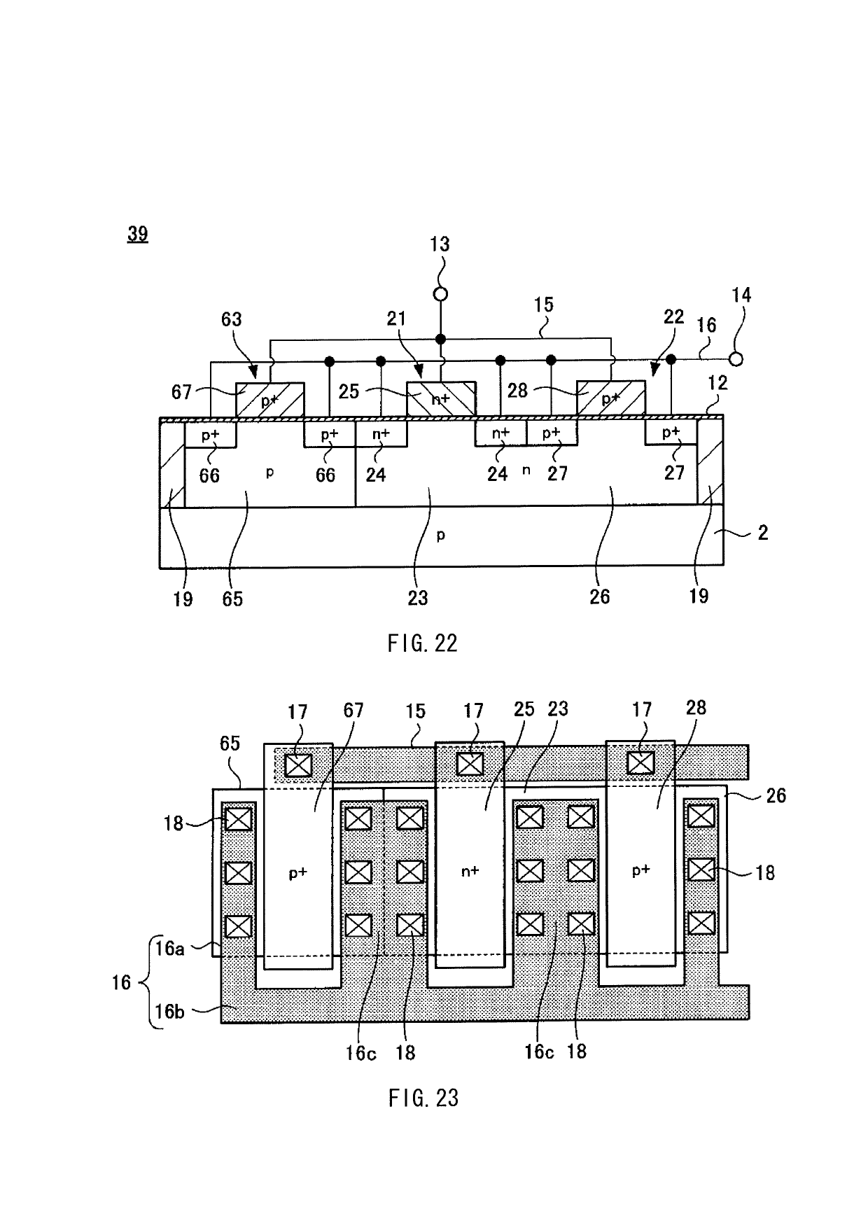

A capacitive device according to a ninth embodiment of the disclosure is now described. FIG. 22 illustrates a schematic sectional configuration of a capacitive device 39 according to the ninth embodiment. FIG. 23 illustrates a planar layout of the capacitive device 39 of the ninth embodiment. In FIGS. 22 and 23, portions corresponding to those in FIGS. 13 and 14 are designated by the same numerals, and duplicated description thereof is omitted. The capacitive device 39 of the ninth embodiment is different from the capacitive device 31 according to the fourth embodiment in that no element separation section 19 is provided in a region between the first capacitive element 22 and the second capacitive element 21, and in a region between the second capacitive element 21 and the third capacitive element 63.

In the ninth embodiment, a first well region 26 is provided in contact with one side of a second well region 23, and a third well region 65 is provided in contact with the other side of the second well region 23. One of the first semiconductor layers 27 configuring the first capacitive element 22 is provided in contact with one of the second semiconductor layers 24 configuring the second capacitive element 21. One of the third semiconductor layers 66 configuring the third capacitive element 63 is provided in contact with the other of the second semiconductor layers 24 configuring the second capacitive element 21.

In the ninth embodiment, as illustrated in FIG. 23, branch lines 16c configuring the second wiring 16 are provided on one of the second semiconductor layers 24 configuring the second capacitive element 21 and on the first semiconductor layer 27 adjacent to the second semiconductor layer 24. The branch lines 16c are connected to the first semiconductor layer 27 and the second semiconductor layer 24 via contacts 18. Similarly, other branch lines 16c configuring the second wiring 16 are provided on the other of the second semiconductor layers 24 configuring the second capacitive element 21 and on the third semiconductor layer 66 adjacent to the other second semiconductor layer 24. The other branch lines 16c are connected to the second semiconductor layer 24 and the third semiconductor layer 66 via contacts 18. The branch lines 16c in the ninth embodiment are provided in common on one first semiconductor layer 27 and on one second semiconductor layer 24 adjacent to the first semiconductor layer 27, and are provided in common on the other second semiconductor layer 24 and on one third semiconductor layer 66 adjacent to the other second semiconductor layer 24.

In the capacitive device 31 according to the fourth embodiment, since the substrate 2 is of a p type, the first well region 26 formed of an n-type impurity layer is electrically floated in the first capacitive element 22 having a structure similar to that of a p-channel MOSFET. To avoid this, an additional well tap is necessary to be provided in the first well region 26 in the fourth embodiment.

In contrast, the first well region 26 and the second well region 23 in the ninth embodiment are each formed of an n-type impurity layer, and are thus electrically connected to each other. As a result, the first well region 26 is electrically connected to the second well region 23 that is electrically fixed by an electric potential received from the second electrode 14 through the second wiring 16, so that the first well region 26 is also electrically fixed. This eliminates the need of an additional well tap in the first well region 26. Consequently, the ninth embodiment achieves a reduction in layout area. In addition, other advantageous effects similar to those in the fourth embodiment are achieved in the ninth embodiment.

Although a common gate insulating film is used for the first to third capacitive elements in the examples of the above-described embodiments (other than the sixth embodiment), the capacitive device of the disclosure should not be limited thereto. The first gate insulating film configuring the first capacitive element, the second gate insulating film configuring the second capacitive element, and the third gate insulating film configuring the third capacitive element may have different materials and different thicknesses. Alternatively, the thickness and/or the material of the first gate insulating film configuring the first capacitive element may be different from the thickness and/or the material of one or both of the second gate insulating film configuring the second capacitive element and the third gate insulating film configuring the third capacitive element.

Although the capacitive device of the disclosure has been described hereinbefore, the capacitive device should not be limited to the first to ninth embodiments, and may be configured in an appropriately combined manner. In addition, the capacitive device of the disclosure may be modified or altered within the scope without departing from the spirit of the disclosure.

The capacitive device according to each of the first to ninth embodiments may be applied to various semiconductor units. A semiconductor unit including a decoupling capacitor and a semiconductor unit including a holding capacitor are now described as a semiconductor unit including the capacitive device of the disclosure.

### 10. Tenth Embodiment

### Semiconductor Unit Including a Decoupling Capacitor

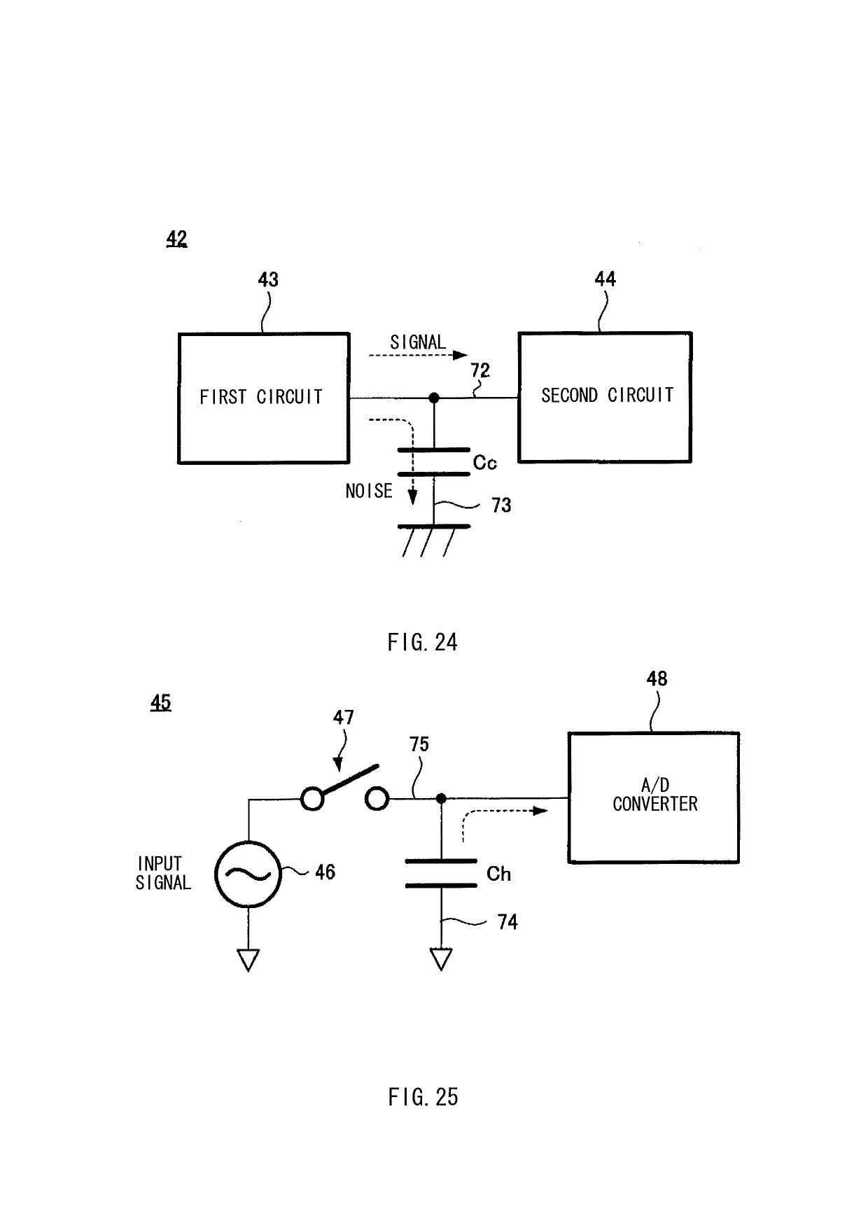

FIG. 24 is a schematic configuration diagram of a semiconductor unit 42 according to a tenth embodiment of the disclosure. As illustrated in FIG. 24, the semiconductor unit 42 of the tenth embodiment includes a first circuit 43, a second circuit 44, and a decoupling capacitor Cc. The decoupling capacitor Cc in the tenth embodiment is connected between a power line 72 connecting the first circuit 43 to the second circuit 44 and a ground line 73. The semiconductor unit 42 of the tenth embodiment includes the capacitive device 1 in the first embodiment as the decoupling capacitor Cc.

In the semiconductor unit 42 of the tenth embodiment, since the decoupling capacitor Cc is provided between the first circuit 43 and the second circuit 44, signals are transmitted from the first circuit 43 to the second circuit 44 while noise components are removed therefrom.

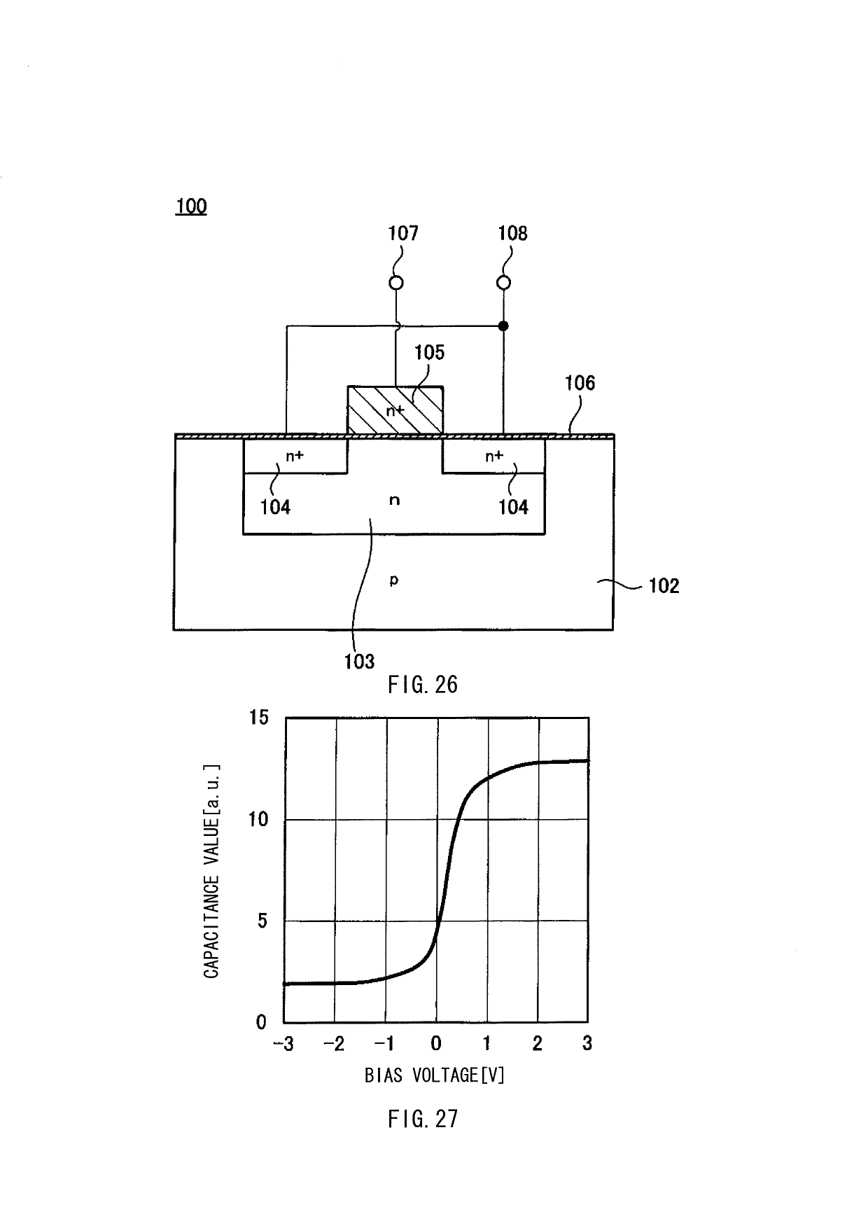

As illustrated in FIG. 27, a capacitance value decreases in a low bias region of 1 V or less in the typical capacitive device illustrated in FIG. 26. Since the impedance of the capacitive device is inversely proportional to a capacitance value, its noise absorption effect is reduced in such a low bias region compared with a bias region of 1 V or more. In contrast, the capacitive device in the tenth embodiment has a small bias dependence of a capacitance value, which prevents a capacitance value from being significantly reduced in the low bias region. As a result, the capacitive device maintains its noise absorption effect even in the low bias region.

### 11. Eleventh Embodiment

### Semiconductor Unit Including a Holding Capacitor

FIG. 25 is a schematic configuration diagram of a semiconductor unit 45 according to an eleventh embodiment of the disclosure. As illustrated in FIG. 25, the semiconductor unit 45 of the eleventh embodiment configures an analog to digital (A/D) conversion circuit, and includes an AC power supply 46, a switch circuit 47, an A/D converter 48, and a holding capacitor Ch. In the semiconductor unit 45 of the eleventh embodiment, the switch circuit 47 is provided between the AC power supply 46 and the A/D converter 48, and the holding capacitor Ch is provided between a line 75 connecting the switch circuit 47 to the A/D converter 48 and a ground line 74. The semiconductor unit 45 of the eleventh embodiment includes the capacitive device 1 in the first embodiment as the holding capacitor Ch.

In the eleventh embodiment, a signal is output from the AC power supply 46 and is received by the A/D converter 48 via the switch circuit 47. In the eleventh embodiment, the holding capacitor Ch is disposed in the previous stage of the A/D converter 48, and thus the signal is maintained at a constant voltage during the conversion processing by the A/D converter 48. This prevents the value of the signal from varying during the conversion processing by the A/D converter 48.

As illustrated in FIG. 27, a capacitance value varies with a value of a bias voltage in the typical capacitive device illustrated in FIG. 26. If such a capacitive device is used for a holding capacitor, charge-and-discharge time of the capacitor greatly varies depending on an input signal level; hence, the circuit of the A/D converter is necessary to be designed in sufficient consideration of such an operation phenomenon. In contrast, the capacitive device in the eleventh embodiment has a small bias dependence of a capacitance value, which ensures relatively constant charge-and-discharge time of the capacitor for an input signal level. As a result, circuit design is facilitated compared with a case using the typical capacitive device.

Although the tenth and eleventh embodiments have been described with an example where the capacitive device 1 according to the first embodiment is used as the capacitor used in the semiconductor unit, the capacitive device according to each of the second to ninth embodiments may be used.

In addition, although the tenth and eleventh embodiments have been described with an example where the capacitive device of the disclosure is used as the decoupling capacitor or the holding capacitor, the capacitive device of the disclosure may be used in any of semiconductor units incorporating various electronic circuits. The electronic circuits in which the capacitive device of the disclosure may be used include a digital to analog (D/A) conversion circuit, an integrating circuit, a comparator circuit, a charge pump circuit, a resonance circuit, a filter circuit, a phase compensating circuit, a smoothing circuit, an operational amplifier (OP), and an electro-static-discharge (ESD) protective circuit.

Each of the semiconductor units may be used for various electronic apparatuses. Examples of the electronic apparatuses, for which each semiconductor unit of the disclosure may be used, include video/audio apparatuses, communication apparatuses, and measuring apparatuses.

Note that the disclosure may be configured as follows.

(1) A capacitive device including:

a first capacitive element including

a first well region having a first conduction type provided in a region close to a surface of a substrate,

a first gate electrode provided on the substrate with a first gate insulating film therebetween, and

first semiconductor layers provided at positions interposing a region therebetween, the region corresponding to the first gate electrode on the surface of the first well region, and the first semiconductor layers each being formed of an impurity layer having a second conduction type opposite to a conduction type of the first well region; and

a second capacitive element electrically connected in parallel to the first capacitive element, the second capacitive element including

a second well region having the first conduction type provided in a region close to the surface of the substrate,

a second gate electrode provided on the substrate with a second gate insulating film therebetween, and

second semiconductor layers provided at positions interposing a region therebetween, the region corresponding to the second gate electrode on the surface of the second well region, and the second semiconductor layers each being formed of an impurity layer having the same first conductive type as a conduction type of the second well region.

(2) The capacitive device according to (1), wherein a ratio of an area of the first gate electrode to an area of the second gate electrode is set to a predetermined value.

(3) The capacitive device according to (1) or (2), further including

a third capacitive element electrically connected in parallel to the first capacitive element and the second capacitive element, the third capacitive element including

a third well region having the second conduction type provided in a region close to the surface of the substrate,

a third gate electrode provided on the substrate with a third gate insulating film therebetween, and

third semiconductor layers provided at positions interposing a region therebetween, the region corresponding to the third gate electrode on the surface of the third well region, and the third semiconductor layers each being formed of an impurity layer having the second conduction type.

(4) The capacitive device according to any one of (1) to (3), wherein each of the first capacitive element, the second capacitive element, and the third capacitive element is provided by one or more on the substrate.

(5) The capacitive device according to any one of (1) to (4), wherein the first gate insulating film has a thickness different from a thickness of one or both of the second gate insulating film and the third gate insulating film.

(6) The capacitive device according to any one of (1) to (5),

wherein a wiring layer is provided above the substrate, the wiring layer having an inter-wiring capacitive element providing capacitance between adjacent lines, and

the inter-wiring capacitive element is electrically connected in parallel to the first capacitive element, the second capacitive element, and the third capacitive element.

(7) The capacitive device according to any one of (1) to (6),

wherein a lower well region formed of an impurity layer having a conduction type opposite to a conduction type of the substrate is provided below part or all of the well regions of the first capacitive element, the second capacitive element, and the third capacitive element.

(8) The capacitive device according to any one of (1) to (7), wherein the first well region is adjacent to the second well region.

(9) A semiconductor unit, including:

a circuit section performing predetermined processing to an input signal; and

a capacitive device provided on an input side of the circuit section, the first capacitive element including a first capacitive element and a second capacitive element electrically connected in parallel to each other,

the first capacitive element including
a first well region having a first conduction type provided in a region close to a surface of a substrate,
a first gate electrode provided on the substrate with a first gate insulating film therebetween, and
first semiconductor layers provided at positions interposing a region therebetween, the region corresponding to the first gate electrode on the surface of the first well region, and the first semiconductor layers each being formed of an impurity layer having a second conduction type opposite to a conduction type of the first well region, and the second capacitive element including
a second well region having the first conduction type provided in a region close to the surface of the substrate,
a second gate electrode provided on the substrate with a second gate insulating film therebetween, and
second semiconductor layers provided at positions interposing a region therebetween, the region corresponding to the second gate electrode on the surface of the second well region, and the second semiconductor layers each being formed of an impurity layer having the same first conductive type as a conduction type of the second well region.

(10) An electronic apparatus provided with a semiconductor unit, the semiconductor unit including:

a circuit section performing predetermined processing to an input signal; and

a capacitive device provided on an input side of the circuit section, the first capacitive element including a first capacitive element and a second capacitive element electrically connected in parallel to each other,

the first capacitive element including
a first well region having a first conduction type provided in a region close to a surface of a substrate,
a first gate electrode provided on the substrate with a first gate insulating film therebetween, and
first semiconductor layers provided at positions interposing a region therebetween, the region corresponding to the first gate electrode on the surface of the first well region, and the first semiconductor layers each being formed of an impurity layer having a second conduction type opposite to a conduction type of the first well region, and the second capacitive element including
a second well region having the first conduction type provided in a region close to the surface of the substrate,
a second gate electrode provided on the substrate with a second gate insulating film therebetween, and
second semiconductor layers provided at positions interposing a region therebetween, the region corresponding to the second gate electrode on the surface of the second well region, and the second semiconductor layers each being formed of an impurity layer having the same first conductive type as a conduction type of the second well region.

The present disclosure contains subject matter related to that disclosed in Japanese Priority Patent Application JP 2012-002442 filed in the Japan Patent Office on Jan. 10, 2012, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A capacitive device comprising:
a first capacitive element including
a first well region having a first conduction type provided in a region close to a surface of a substrate,
a first gate electrode provided on the substrate with a first gate insulating film therebetween, and
first semiconductor layers provided at positions interposing a region therebetween, the region corresponding to the first gate electrode on the surface of the first well region, and the first semiconductor layers each being formed of an impurity layer having a second conduction type opposite to a conduction type of the first well region; and
a second capacitive element electrically connected in parallel to the first capacitive element, the second capacitive element including
a second well region having the first conduction type provided in a region close to the surface of the substrate,
a second gate electrode provided on the substrate with a second gate insulating film therebetween, and
second semiconductor layers provided at positions interposing a region therebetween, the region corresponding to the second gate electrode on the surface of the second well region, and the second semiconductor layers each being formed of an impurity layer having the same first conductive type as a conduction type of the second well region.

2. The capacitive device according to claim 1, wherein a ratio of an area of the first gate electrode to an area of the second gate electrode is set to a predetermined value.

3. The capacitive device according to claim 2, further comprising
a third capacitive element electrically connected in parallel to the first capacitive element and the second capacitive element, the third capacitive element including
a third well region having the second conduction type provided in a region close to the surface of the substrate,
a third gate electrode provided on the substrate with a third gate insulating film therebetween, and
third semiconductor layers provided at positions interposing a region therebetween, the region corresponding to the third gate electrode on the surface of the third well region, and the third semiconductor layers each being formed of an impurity layer having the second conduction type.

4. The capacitive device according to claim 3, wherein each of the first capacitive element, the second capacitive element, and the third capacitive element is provided by one or more on the substrate.

5. The capacitive device according to claim 4, wherein the first gate insulating film has a thickness different from a thickness of one or both of the second gate insulating film and the third gate insulating film.

6. The capacitive device according to claim 5,
wherein a wiring layer is provided above the substrate, the wiring layer having an inter-wiring capacitive element providing capacitance between adjacent lines, and
the inter-wiring capacitive element is electrically connected in parallel to the first capacitive element, the second capacitive element, and the third capacitive element.

7. The capacitive device according to claim 6,
wherein a lower well region formed of an impurity layer having a conduction type opposite to a conduction type of the substrate is provided below part or all of the well regions of the first capacitive element, the second capacitive element, and the third capacitive element.

8. The capacitive device according to claim 7, wherein the first well region is adjacent to the second well region.

9. A semiconductor unit, comprising:
a circuit section performing predetermined processing to an input signal; and
a capacitive device provided on an input side of the circuit section, the first capacitive element including a first capacitive element and a second capacitive element electrically connected in parallel to each other,
the first capacitive element including
a first well region having a first conduction type provided in a region close to a surface of a substrate,
a first gate electrode provided on the substrate with a first gate insulating film therebetween, and
first semiconductor layers provided at positions interposing a region therebetween, the region corresponding to the first gate electrode on the surface of the first well region, and the first semiconductor layers each being formed of an impurity layer having a second conduction type opposite to a conduction type of the first well region, and
the second capacitive element including
a second well region having the first conduction type provided in a region close to the surface of the substrate,
a second gate electrode provided on the substrate with a second gate insulating film therebetween, and
second semiconductor layers provided at positions interposing a region therebetween, the region corresponding to the second gate electrode on the surface of the second well region, and the second semiconductor layers each being formed of an impurity layer having the same first conductive type as a conduction type of the second well region.

10. An electronic apparatus provided with a semiconductor unit, the semiconductor unit comprising:
a circuit section performing predetermined processing to an input signal; and
a capacitive device provided on an input side of the circuit section, the first capacitive element including a first capacitive element and a second capacitive element electrically connected in parallel to each other,
the first capacitive element including
a first well region having a first conduction type provided in a region close to a surface of a substrate,
a first gate electrode provided on the substrate with a first gate insulating film therebetween, and
first semiconductor layers provided at positions interposing a region therebetween, the region corresponding to the first gate electrode on the surface of the first well region, and the first semiconductor layers each being formed of an impurity layer having a second conduction type opposite to a conduction type of the first well region, and
the second capacitive element including
a second well region having the first conduction type provided in a region close to the surface of the substrate,
a second gate electrode provided on the substrate with a second gate insulating film therebetween, and
second semiconductor layers provided at positions interposing a region therebetween, the region corresponding to the second gate electrode on the surface of the second well region, and the second semiconductor layers each being formed of an impurity layer having the same first conductive type as a conduction type of the second well region.
